(19) United States
(12) Patent Application Publication
(10) Pub. No.: US 2021/0288194 A1
(43) Pub. Date: Sep. 16, 2021

(54) METHODS AND SYSTEMS FOR GENERATING ALTERNATING CURRENT BY LIGHT

(71) Applicant: Georgia Tech Research Corporation, Atlanta, GA (US)

(72) Inventors: Zhong Lin Wang, Atlanta, GA (US); Haiyang Zou, Atlanta, GA (US)

(21) Appl. No.: 17/203,417

(22) Filed: Mar. 16, 2021

Related U.S. Application Data
(60) Provisional application No. 62/990,301, filed on Mar. 16, 2020.

(51) Int. Cl. H01L 31/0224; H01L 31/02; H02S 10/00

(52) U.S. Cl. CPC H01L 31/022425; H01L 31/02008; H02S 10/00; H01L 31/02021

(57) ABSTRACT

An exemplary embodiment of the present disclosure provides an alternating current (AC) generator comprising a substrate comprising a first material abutting a second material and forming an interface, wherein the first material comprises a first electrode and the second material comprises a second electrode in electrical communication with the first electrode, and wherein the substrate is configured to generate AC when the interface is exposed to periodic light stimulation.

### CROSS-REFERENCE TO RELATED APPLICATIONS

This application claims the benefit of U.S. Provisional Application Ser. No. 62/990,301, filed on 16 Mar. 2020, which is incorporated herein by reference in its entirety as if fully set forth below.

### FEDERALLY SPONSORED RESEARCH STATEMENT

This invention was made with government support under grant/award number DE-FG02-07ER46394 awarded by the U.S. Department of Energy, Office of Basic Energy Sciences, and grant/award number DMR-1505319, awarded by the National Science Foundation. The government has certain rights in the invention.

### FIELD OF THE DISCLOSURE

The various embodiments of the present disclosure relate generally to systems and methods for generating alternating current, and more particularly to photodetectors and/or photovoltaics generating alternating current under periodic light stimulation.

### BACKGROUND

Systems and methods for that covert light energy into electrical energy, such as photovoltaics and solar cells, have been used in a variety of applications due to the unique properties of directional separation of light-excited charge carriers (either an electron or a hole, together forming an electron-hole pair), within a semiconductor material. Semiconductor materials can intrinsic (i-type) or can be doped with either electron donor dopants (n-type) or electron acceptor dopants (p-type). When semiconductor materials having different concentrations of charge carriers or doping are in contact, a junction or interface is formed at the site. A p-n junction is a common type of interface used for generating electron-hole pairs under continuous illumination, known as the photovoltaic effect.

In a conventional p-n junction system, electric charges flow in one direction and generate a direct current (DC). Importantly, the conventional photovoltaic effect does not generate an alternating current since electrons can only flow through the junction from n to p and not from p to n. Under a forward voltage bias at the p-n junction, electric charge flows freely, but a reverse voltage bias generates resistance and charge flow is negligible. The energy generated from the conventional photovoltaic effect is limited to direct current and requires a battery to store the electrical energy produced under continuous illumination. There is a need to develop systems and methods for converting light into alternating current (AC) with high efficiency and sensitivity without external applied bias. Systems and methods that generate AC from periodic light stimulation at an interface within a single device can be used as a renewable energy source for any electronic device relying on power from an outlet as well as sensors and photodetectors.

### BRIEF SUMMARY

The present disclosure relates to alternating current (AC) generators. An exemplary embodiment of the present disclosure provides an AC generator comprising a substrate comprising a first material abutting a second material and forming an interface. The first material can comprise a first electrode. The second material can comprise a second electrode in electrical communication with the first electrode. The substrate can be configured to generate alternating current (AC) when the interface is exposed to periodic light stimulation.

In any of the embodiments disclosed herein, the substrate can be configured to generate the AC when the interface is exposed to periodic light stimulation while a relatively small bias voltage or no bias is applied to the first and the second materials. The bias voltage can range from 0 V to about 0.2 V.

In any of the embodiments disclosed herein, the periodic light stimulation can comprise a range from about 100 nm to about 2500 nm.

In any of the embodiments disclosed herein, the interface can be exposed to the periodic light stimulation comprising modulated waveforms of a light source.

In any of the embodiments disclosed herein, the waveforms can comprise a square waveform, a sinusoidal waveform, a triangular waveform, a sawtooth waveform, a step waveform, or a pulsed waveform.

In any of the embodiments disclosed herein, the interface can be exposed to the periodic light stimulation comprising consecutively blocked and unblocked light stimulation to the interface.

In any of the embodiments disclosed herein, the interface can be exposed to the periodic light stimulation comprising consecutively blocked and unblocked light stimulation at a frequency of about 0.1 Hz to about 1 GHz.

In any of the embodiments disclosed herein, the first material can comprise a p-type material, an n-type material, an i-type material, a metal, or a semiconductor. The second material can comprise a p-type material, an n-type material, an intrinsic-type material, an insulator material, a metal, or a semiconductor.

In any of the embodiments disclosed herein, the interface can comprise at least one of a p-n junction, a p-intrinsic-n junction, a p-insulator-n junction, or a metal-semiconductor junction.

An exemplary embodiment of the present disclosure provides a method for generating alternating current. The method can comprise exposing an interface formed on a substrate to periodic light stimulation, generating an alternating current (AC), and outputting the AC at the first and second electrodes. The substrate can comprise a first material abutting a second material. The interface can be positioned between the first material and the second material. The first material can have a first electrode. The second material can have a second electrode in electrical communication with the first electrode.

In any of the embodiments disclosed herein, the method can further comprise applying a bias voltage to the first and second materials. The bias voltage can range from 0 V to about 0.2 V.

In any of the embodiments disclosed herein, the interface can comprise at least one of a p-n junction, a p-intrinsic-n junction, a p-insulator-n junction, or a metal-semiconductor junction.

In any of the embodiments disclosed herein, the periodic light stimulation can comprise a range from about 100 nm to about 2500 nm.

In any of the embodiments disclosed herein, exposing the interface to the periodic light stimulation can comprise modulating waveforms of a light source.

In any of the embodiments disclosed herein, the waveforms can comprise a square waveform, a sinusoidal waveform, a triangular waveform, a sawtooth waveform, a step waveform, or a pulsed waveform.

In any of the embodiments disclosed herein, exposing the interface to the periodic light stimulation can comprise consecutively blocking and unblocking light stimulation to the interface at a frequency of about 0.1 Hz to about 1 GHz.

An exemplary embodiment of the present disclosure provides a sensor. The sensor can comprise a semiconductor having an interface formed between a first material and an abutting second material. The interface can be configured to generate an electrical signal when exposed to periodic light stimulation.

In any of the embodiments disclosed herein, the interface can be configured to generate an electrical signal when exposed to periodic light stimulation. A bias voltage can be applied to the first and second materials. The bias voltage can range from 0 V to about 0.2 V.

In any of the embodiments disclosed herein, the periodic light stimulation can comprise a range from about 100 nm to about 2500 nm.

In any of the embodiments disclosed herein, the interface can comprise at least one of a p-n junction, a p-intrinsic-n junction, a p-insulator-n junction, or a metal-semiconductor j unction.

These and other aspects of the present disclosure are described in the Detailed Description below and the accompanying drawings. Other aspects and features of embodiments will become apparent to those of ordinary skill in the art upon reviewing the following description of specific, exemplary embodiments in concert with the drawings. While features of the present disclosure may be discussed relative to certain embodiments and figures, all embodiments of the present disclosure can include one or more of the features discussed herein. Further, while one or more embodiments may be discussed as having certain advantageous features, one or more of such features may also be used with the various embodiments discussed herein. In similar fashion, while exemplary embodiments may be discussed below as device, system, or method embodiments, it is to be understood that such exemplary embodiments can be implemented in various devices, systems, and methods of the present disclosure.

### BRIEF DESCRIPTION OF THE DRAWINGS

The following detailed description of specific embodiments of the disclosure will be better understood when read in conjunction with the appended drawings. For the purpose of illustrating the disclosure, specific embodiments are shown in the drawings. It should be understood, however, that the disclosure is not limited to the precise arrangements and instrumentalities of the embodiments shown in the drawings.

FIG. 1A provides a schematic of an example substrate for generating alternating current (AC) under periodic light, in accordance with exemplary embodiments of the present disclosure.

FIG. 1B provides a schematic of an example substrate for generating alternating current (AC) under periodic light, in accordance with exemplary embodiments of the present disclosure.

FIG. 2A provides a measurement setup of an example substrate for generating alternating current (AC) under the periodic light stimulation under a flashing light at different chopper frequencies, in accordance with an exemplary embodiment of the present disclosure.

FIG. 2B shows an enlarged typical current versus time (I-t) curve under the periodic light stimulation showing a dash line at 0 A, a flat region below 0 A representing the direct current (DC) based on conventional photovoltaic (PV) effect, and a current peak representing the alternating current based on the AC PV effect when the light is switched on or off, in accordance with an exemplary embodiment of the present disclosure.

FIG. 3A shows a plot of current (μA) versus time (s) (I-t) characteristics and voltage (mV) versus time (s) (V-t) characteristics of an example substrate for generating AC under 442 nm illumination with 7.79 mW/cm² at different chopper frequencies (2-1000 Hz), in accordance with an exemplary embodiment of the present disclosure.

FIG. 3B shows a plot of current (μA) versus time (s) (I-t) characteristics and voltage (mV) versus time (s) (V-t) characteristics of an example substrate for generating AC under 442 nm illumination with 7.79 mW/cm² at different chopper frequencies (2-1000 Hz), in accordance with an exemplary embodiment of the present disclosure.

FIG. 4A shows the relationship between response time and frequency of an example substrate for generating AC, in accordance with an exemplary embodiment of the present disclosure.

FIG. 4B shows the relationship between response time and frequency with on-off time of an example substrate for generating AC, in accordance with an exemplary embodiment of the present disclosure.

FIG. 4C shows the relationship between response time and frequency with specific on time of an example substrate for generating AC, in accordance with an exemplary embodiment of the present disclosure.

FIG. 4D shows the relationship between response time and frequency with specific off time of an example substrate for generating AC, in accordance with an exemplary embodiment of the present disclosure.

FIG. 4E shows the relationship between response time and frequency with total on time of an example substrate for generating AC, in accordance with an exemplary embodiment of the present disclosure.

FIG. 4F shows the relationship between response time and frequency with total off time of an example substrate for generating AC, in accordance with an exemplary embodiment of the present disclosure.

FIG. 5A shows a plot of current (μA) versus time (s) (I-t) characteristics and open-circuit voltage (mV) versus time (s) (V-t) characteristics of an example substrate for generating AC under 442 nm illumination with different power densities ranging from 0.18 to 7.79 mW/cm² at 800 Hz, in accordance with an exemplary embodiment of the present disclosure.

FIG. 5B shows a plot of current (μA) versus time (s) (I-t) characteristics and open-circuit voltage (mV) versus time (s) (V-t) characteristics of an example substrate for generating AC under 442 nm illumination with different power densities ranging from 0.18 to 7.79 mW/cm² at 800 Hz, in accordance with an exemplary embodiment of the present disclosure.

FIG. 6 provides plots of current (μA) versus time (s) (I-t) characteristics of an example substrate for generating AC under 442 nm light with 7.79 mW/cm² with different illumination area (diameters range from 1 to 8 mm), in accordance with an exemplary embodiment of the present disclosure.

FIG. 7 provides images of plates having center hole cuttings by laser cutter for controlling the illumination area size to substrates generating AC under periodic light stimulation, in accordance with an exemplary embodiment of the present disclosure.

FIG. 8 shows a plot of current (μA) versus time (s) (I-t) characteristics for long-term durability and stability of an example substrate for generating AC under 442 nm illumination of 7.79 mW/cm² at 1,000 Hz, in accordance with an exemplary embodiment of the present disclosure.

FIG. 9A shows a plot of current (μA) versus time (s) (I-t) characteristics of a junction of an example substrate for generating AC under illumination of 325 nm with a chopper frequency of 1,000 Hz, in accordance with an exemplary embodiment of the present disclosure.

FIG. 9B shows a plot of current (μA) versus time (s) (I-t) characteristics of a junction of an example substrate for generating AC under illumination of 442 nm with a chopper frequency of 1,000 Hz, in accordance with an exemplary embodiment of the present disclosure.

FIG. 9C shows a plot of current (μA) versus time (s) (I-t) characteristics of a junction of an example substrate for generating AC under illumination of 808 nm with a chopper frequency of 1,000 Hz, in accordance with an exemplary embodiment of the present disclosure.

FIG. 9D shows a plot of current (μA) versus time (s) (I-t) characteristics of a junction of an example substrate for generating AC under illumination of 1,060 nm with a chopper frequency of 1,000 Hz, in accordance with an exemplary embodiment of the present disclosure.

FIG. 10A shows a plot of current (μA) versus voltage (V) (I-V) characteristics of a Shottky contact (Al-pSi-ITO) junction in the dark.

FIG. 10B shows a plot of current (μA) versus time (s) (I-t) characteristics of a Shottky contact (Al-pSi-ITO) junction under the 442 nm illumination with a power density of 7.79 mW/cm² and a chopper frequency of 20 Hz, in accordance with an exemplary embodiment of the present disclosure.

FIG. 10C shows a plot of current (μA) versus voltage (V) (I-V) characteristics of an Ohmic contact (ITO-pSi-ITO junction in the dark.

FIG. 10D shows a plot of current (μA) versus time (s) (I-t) characteristics of an Ohmic contact (ITO-pSi-ITO) junction under the 442 nm illumination with a power density of 7.79 mW/cm² and a chopper frequency of 20 Hz, in accordance with an exemplary embodiment of the present disclosure.

FIG. 10E shows a plot of current (μA) versus voltage (V) (I-V) characteristics of a Metal-Insulator-Semiconductor (pSi-AlOx-ITO) junction in the dark.

FIG. 10F shows a plot of current (μA) versus time (s) (I-t) characteristics of a Metal-Insulator-Semiconductor (pSi-AlOx-ITO) junction under the 442 nm illumination with a power density of 7.79 mW/cm² and a chopper frequency of 20 Hz, in accordance with an exemplary embodiment of the present disclosure.

FIG. 10G shows a plot of current (μA) versus voltage (V) (I-V) characteristics of a P-Insulator-N(pSi-AlOx-ZnO nanowire arrays) junction in the dark.

FIG. 10H shows a plot of current (μA) versus time (s) (I-t) characteristics of a P-Insulator-N(pSi-AlOx-ZnO nanowire arrays) junction under the 442 nm illumination with a power density of 7.79 mW/cm² and a chopper frequency of 20 Hz, in accordance with an exemplary embodiment of the present disclosure.

FIG. 11 depicts a connection scheme and a plot of current (μA) versus time (s) (I-t) of an example substrate device 1 (“Dev 1”) under the illumination of 442 nm light at 800 Hz, in accordance with an exemplary embodiment of the present disclosure.

FIG. 12 depicts a connection scheme and a plot of current (μA) versus time (s) (I-t) of an example substrate device 2 (“Dev 2”) under the illumination of 442 nm light at 800 Hz, in accordance with an exemplary embodiment of the present disclosure.

FIG. 13A depicts a connection scheme and plot of current (μA) versus time (s) (I-t) of an example configuration for two devices (“Dev 1” and “Dev 2”) connected in parallel, in accordance with exemplary embodiments of the present disclosure.

FIG. 13B depicts a connection scheme and plot of current (μA) versus time (s) (I-t) of an example configuration for two devices (“Dev 1” and “Dev 2”) connected in parallel, in accordance with exemplary embodiments of the present disclosure.

FIG. 13C depicts a connection scheme and plot of current (μA) versus time (s) (I-t) of an example configuration for two devices (“Dev 1” and “Dev 2”) connected in parallel, in accordance with exemplary embodiments of the present disclosure.

FIG. 13D depicts a connection scheme and plot of current (μA) versus time (s) (I-t) of an example configuration for two devices (“Dev 1” and “Dev 2”) connected in parallel, in accordance with exemplary embodiments of the present disclosure.

FIG. 14 depicts a connection scheme and a plot of voltage (V) versus time (s) (V-t) of an example substrate device 1 (“Dev 1”) under the illumination of 442 nm light at 800 Hz, in accordance with an exemplary embodiment of the present disclosure.

FIG. 15 depicts a connection scheme and a plot of voltage (V) versus time (s) (V-t) of an example substrate device 2 (“Dev 2”) under the illumination of 442 nm light at 800 Hz, in accordance with an exemplary embodiment of the present disclosure.

FIG. 16A depicts a connection scheme and plot of voltage (V) versus time (s) (V-t) of an example configuration for two devices (“Dev 1” and “Dev 2”) connected in a series, in accordance with exemplary embodiments of the present disclosure.

FIG. 16B depicts a connection scheme and plot of voltage (V) versus time (s) (V-t) of an example configuration for two devices (“Dev 1” and “Dev 2”) connected in a series, in accordance with exemplary embodiments of the present disclosure.

FIG. 16C depicts a connection scheme and plot of voltage (V) versus time (s) (V-t) of an example configuration for two devices (“Dev 1” and “Dev 2”) connected in a series, in accordance with exemplary embodiments of the present disclosure.

FIG. 16D depicts a connection scheme and plot of voltage (V) versus time (s) (V-t) of an example configuration for two devices (“Dev 1” and “Dev 2”) connected in a series, in accordance with exemplary embodiments of the present disclosure.

FIG. 17 shows a charging curve of a capacitor charged by AC output from an example substrate for generating AC under illumination under the illumination of 442 nm laser at 1,000 Hz, in accordance with an exemplary embodiment of the present disclosure.

FIG. 18A shows an energy band diagram of a junction in the dark, with a conduction band (CB), a valence band (VB), and a Fermi level shown as a dotted line.

FIG. 18B shows an energy band diagram of a junction with a light on, with excess electrons and holes generated, a quasi-Fermi level shift, and a negative current peak generated as a result of electrons flowing from the right electrode to the left electrode to balance the Fermi levels.

FIG. 18C shows a system reaching a new thermal equilibrium under illumination.

FIG. 18D shows an energy band diagram of a junction with a light off, a quasi-Fermi level shift, and a positive current peak generated as the electrons flow back from the left electrode to the right electrode.

FIG. 19 shows a plot of current (μA) versus time (s) (I-t) characteristics of an example substrate for generating AC under the illumination of 442 nm light at frequency of 800 Hz, in accordance with an exemplary embodiment of the present disclosure.

FIG. 20 shows a typical electrical output in current (μA) versus time (s) of a photodetector based on an example substrate for generating AC under periodic light stimulation, in accordance with an exemplary embodiment of the present disclosure.

FIG. 21A shows an example substrate having a vertical structure for generating AC under illumination, like sandwich structure, having two electrodes at the different sides of the silicon wafer, in accordance with an exemplary embodiment of the present disclosure.

FIG. 21B shows an example substrate having a planar structure for generating AC under illumination having two electrodes at the same sides of the silicon wafer, in accordance with an exemplary embodiment of the present disclosure.

FIG. 21C shows a plot of current (μA) versus time (s) (I-t) characteristic of a planar Metal-Semiconductor junction of ITO/p-Si/ITO under the illumination of 442 nm at the chopper frequency of 20 Hz with zero bias, in accordance with an exemplary embodiment of the present disclosure.

FIG. 21D shows a plot of current (μA) versus time (s) (I-t) characteristic of a planar Metal-Semiconductor-Metal junction of Cu/p-Si/Cu under the illumination of 442 nm at the chopper frequency of 20 Hz with zero bias, in accordance with an exemplary embodiment of the present disclosure.

FIG. 22A shows an example planar structure of Cu/p-Si/Cu, in accordance with an exemplary embodiment of the present disclosure.

FIG. 22B shows electrical output of an example planar structure of Cu/p-Si/Cu for generating AC under illumination of 442 m light at 1000 Hz at point “x” above a middle point.

FIG. 22C shows electrical output of an example planar structure of Cu/p-Si/Cu for generating AC under illumination of 442 m light at 1000 Hz at point “y” at a middle point.

FIG. 22D shows electrical output of an example planar structure of Cu/p-Si/Cu for generating AC under illumination of 442 m light at 1000 Hz at point “z” below a middle point.

FIG. 23A shows an example planar structure of Cu/p-Si/Cu, in accordance with an exemplary embodiment of the present disclosure.

FIG. 23B shows electrical output in current (μA) versus time (s) of an example planar structure of Cu/p-Si/Cu for generating AC under illumination of 442 m light at 1000 Hz at point “x” at an interface of two materials.

FIG. 23C shows electrical output in current (μA) versus time (s) of an example planar structure of Cu/p-Si/Cu for generating AC under illumination of 442 m light at 1000 Hz at point “y” at a middle point between two electrodes.

FIG. 24A shows an example planar structure of Cu/Au on different substrate, in accordance with an exemplary embodiment of the present disclosure.

FIG. 24B shows electrical output in current (A) versus time (s) of an example planar structure of Cu/Au under the illumination of 442 nm with 7.79 mW/cm² on glass substrate. The inset is the enlarged figures start from 2 seconds to 6 seconds.

FIG. 24C shows electrical output in current (A) versus time (s) of an example planar structure of Cu/Au under the illumination of 442 nm with 7.79 mW/cm² on Si substrate. The inset is the enlarged figures start from 2 seconds to 6 seconds.

FIG. 25A shows electrical output in current (μA) versus time (s) of a p-Si/TiO₂ device under the illumination at 642 nm at a frequency of 20 Hz, in accordance with an exemplary embodiment of the present disclosure.

FIG. 25B shows electrical output in current (μA) versus time (s) of a commercial solar cell under the illumination at 642 nm at a frequency of 20 Hz, in accordance with an exemplary embodiment of the present disclosure.

FIG. 25C shows electrical output in current (μA) versus time (s) of an organic solar cell under the illumination at 642 nm at a frequency of 20 Hz, in accordance with an exemplary embodiment of the present disclosure.

FIG. 26A shows a plot of current versus time (I-t) characteristics of an example substrate for generating AC under the illumination of near-infrared light at 1545 nm under a high light intensity, in accordance with an exemplary embodiment of the present disclosure.

FIG. 26B shows a plot of current versus time (I-t) characteristics of an example substrate for generating AC under the illumination of near-infrared light at 1545 nm under a low light intensity, in accordance with an exemplary embodiment of the present disclosure.

FIG. 27A shows a plot of current (μA) versus time (s) (I-t) characteristics of an example substrate for generating AC under the illumination when a metal probe is contacted with the surface of the substrate, in accordance with an exemplary embodiment of the present disclosure.

FIG. 27B shows a plot of current (μA) versus time (s) (I-t) characteristics of an example substrate for generating AC under the illumination when a rubber rod is contacted with the surface of the substrate, in accordance with an exemplary embodiment of the present disclosure.

FIG. 28A shows a plot of sensitivity (%) versus power density (mW/cm²) representing the sensitivity of an example substrate for generating AC under different illumination power densities compared to the value from a conventional photovoltaic effect (continuous light stimulation) with an inset showing a conventional photovoltaic effect (continuous light stimulation) at −2 V and 0 V.

FIG. 28B shows the sensitivity of an example substrate for generating AC under ultra-low light intensities, in accordance with an exemplary embodiment of the present disclosure.

FIG. 29A shows a plot of current (μA) versus time (s) (I-t) representing the response time of an example substrate as a photodetector without illumination (I, shaded region) and under the illumination of 442 nm at 1000 Hz (II, unshaded region).

FIG. 29B shows an enlarged plot current (μA) versus time (s) representing the response time under periodic light stimulation, in accordance with an exemplary embodiment of the present disclosure.

FIG. 30 shows a plot of voltage (V) versus time (s) for an open circuit voltage (V_{OC}) (top) and a plot of current (μA) versus time (s) for a short circuit current (I_{SC}) in dark (A), continual light stimulation (B), and periodic light stimulation at 1000 Hz (C), in accordance with an exemplary embodiment of the present disclosure.

FIG. 31 shows a dual plot of voltage (V) versus resistance (Ω) and current (μA) versus resistance (Ω) representing the dependence of the voltage and current output on external load resistances of a commercial solar panel by conventional PV effect (top) and a dual plot of voltage (V) versus resistance (Ω) and current (μA) versus resistance (Ω) representing the dependence of the voltage and current output on external load resistances of an example substrate for generating AC (bottom), in accordance with an exemplary embodiment of the present disclosure.

FIG. 32 shows a plot of power (μW) versus resistance (Ω) representing the dependence of the output power on the load resistances of a commercial solar cell under continuous light stimulation (top) and the dependence of the output power on the load resistances of a commercial solar cell under a periodic light stimulation with a chopper frequency of 1000 Hz (bottom), in accordance with an exemplary embodiment of the present disclosure.

FIG. 33A shows a plot of current (μA) versus time (s) (I-t) characteristics for an example substrate for generating AC under the illumination of 442 nm wavelength light and a chopper frequency of 20 Hz at applied bias voltages of 2 V, in accordance with an exemplary embodiment of the present disclosure.

FIG. 33B shows a plot of current (μA) versus time (s) (I-t) characteristics for an example substrate for generating AC under the illumination of 442 nm wavelength light and a chopper frequency of 20 Hz at applied bias voltages of 0.5 V, in accordance with an exemplary embodiment of the present disclosure.

FIG. 33C shows a plot of current (μA) versus time (s) (I-t) characteristics for an example substrate for generating AC under the illumination of 442 nm wavelength light and a chopper frequency of 20 Hz at applied bias voltages of 0.1, 0 V, and −0.1 V, in accordance with an exemplary embodiment of the present disclosure.

FIG. 33D shows a plot of current (μA) versus time (s) (I-t) characteristics for an example substrate for generating AC under the illumination of 442 nm wavelength light and a chopper frequency of 20 Hz at applied bias voltages −1 V, in accordance with an exemplary embodiment of the present disclosure.

FIG. 34A shows a schematic of the status of allowed energy levels on the surface under reverse bias, in accordance with an exemplary embodiment of the present disclosure.

FIG. 34B shows a schematic of the status of allowed energy levels on the surface under forward bias, in accordance with an exemplary embodiment of the present disclosure.

FIG. 35 shows a dual plot of current density (μA/cm²) versus resistance (Ω) and energy density (Wh/L) versus resistance (Ω) of an example substrate for generating AC with different external load resistances varying from 1Ω to 1 MΩ, in accordance with an exemplary embodiment of the present disclosure.

FIG. 36 shows an example experimental setup for AC measurement under low temperature in a vacuum chamber under the illumination of a LED, in accordance with an exemplary embodiment of the present disclosure.

FIG. 37A shows a dual plot of voltage (V) versus time (s) and current (μA) versus time (s) (I-t) characteristics representing current output under various waveforms of modulated light including triangular waveforms of input, in accordance with exemplary embodiments of the present disclosure.

FIG. 37B shows a dual plot of voltage (V) versus time (s) and current (μA) versus time (s) (I-t) characteristics representing current output under various waveforms of modulated light including sinusoidal waveforms of input, in accordance with exemplary embodiments of the present disclosure.

FIG. 37C shows a dual plot of voltage (V) versus time (s) and current (μA) versus time (s) (I-t) characteristics representing current output under various waveforms of modulated light including square waveforms of input, in accordance with exemplary embodiments of the present disclosure.

FIG. 38A provides a plot of current (μA) versus time (s) I-t curves of an example substrate for generating AC under a triangular waveform of voltage input from a function generator, in accordance with exemplary embodiments of the present disclosure.

FIG. 38B provides a plot of current (μA) versus time (s) I-t curves of an example substrate for generating AC under a sine waveform of voltage input from a function generator, in accordance with exemplary embodiments of the present disclosure.

FIG. 38C provides a plot of current (μA) versus time (s) I-t curves of an example substrate for generating AC under a square waveform of voltage input from a function generator, in accordance with exemplary embodiments of the present disclosure.

FIG. 39A shows a plot of current (μA) versus frequency (Hz) representing the effect of frequency of light on the peak current outputs of an example substrate for generating AC under the illumination in triangular waveform of voltage inputs modulated by a function generator, in accordance with an exemplary embodiment of the present disclosure.

FIG. 39B shows a plot of current (μA) versus frequency (Hz) representing the effect of frequency of light on the peak current outputs of an example substrate for generating AC under the illumination in square waveform of voltage inputs modulated by a function generator, in accordance with an exemplary embodiment of the present disclosure.

FIG. 40 shows a plot of current (μA) versus time (s) representing electric output of an example substrate acting as a photodetector is under dark and modulated light. The inset is the enlarged figure of the AC output under the modulated light, in accordance with an exemplary embodiment of the present disclosure.

FIG. 41 shows a plot of sensitivity (%) versus intensity (mW/cm²) representing sensitivity of an example substrate for generating AC under various intensities of illumination based on alternating current photo-response and the conventional photovoltaic effect, in accordance with an exemplary embodiment of the present disclosure.

FIG. 42 show a plot of sensitivity (%) of an example substrate for generating AC under illumination compared to photodetectors based on different types of materials, in accordance with an exemplary embodiment of the present disclosure.

FIG. 43 shows a plot of current (μA) versus time (s) (I-t) characteristics of an example substrate for generating AC under the illumination with different power densities ranging from 1.3 μW cm⁻² to 0.87 mW cm⁻², in accordance with an exemplary embodiment of the present disclosure.

FIG. 44 shows a plot of current (μA) versus time (s) (I-t) under dark current of an example substrate for generating AC under negative voltage of about 1 V, in accordance with an exemplary embodiment of the present disclosure.

FIG. 45 shows a plot of current (μA) versus time (s) (I-t) of an example substrate for generating AC measured 3 years apart, accordance with an exemplary embodiment of the present disclosure.

FIG. 46A provides an image of a micro-manipulation cryogenic probe system for measuring the output an enlarged image of the sample stage, in accordance with an exemplary embodiment of the present disclosure.

FIG. 46B provides an image of a micro-manipulation cryogenic probe system for measuring the output an enlarged image of the sample stage, in accordance with an exemplary embodiment of the present disclosure.

FIG. 47A provides an image of a micro-manipulation cryogenic probe system and a chamber lid having a window to allow light to shine upon the sample substrate for generating AC, in accordance with an exemplary embodiment of the present disclosure.

FIG. 47B provides an image of a micro-manipulation cryogenic probe system and a chamber lid having a window to allow light to shine upon the sample substrate for generating AC, in accordance with an exemplary embodiment of the present disclosure.

FIG. 48A shows a plot of current (μA) versus time (s) (I-t) of an example substrate comprising p-Si/TiO₂ for generating AC under periodic light stimulation various temperature ranging from 78 K to 293 K, in accordance with an exemplary embodiment of the present disclosure.

FIG. 48B shows a dual plot of positive current (μA) versus time (s) (left axis) and negative current (μA) versus inverse temperature (K⁻¹) (right axis) of an example substrate comprising p-Si/TiO₂ for generating AC under periodic light stimulation various temperature ranging from 78 K to 293 K, in accordance with an exemplary embodiment of the present disclosure.

FIG. 49A shows a plot of current (μA) versus time (s) (I-t) of an example substrate comprising p-Si/ZnO for generating AC under periodic light stimulation various temperature ranging from 78 K to 293 K, in accordance with an exemplary embodiment of the present disclosure.

FIG. 49B shows a dual plot of positive current (μA) versus time (s) (left axis) and negative current (μA) versus inverse temperature (K⁻¹) (right axis) of an example substrate comprising p-Si/ZnO for generating AC under periodic light stimulation various temperature ranging from 78 K to 293 K, in accordance with an exemplary embodiment of the present disclosure.

FIG. 50A shows a plot of current (A) versus voltage (V) of an example substrate comprising p-Si/ZnO from −2 to −1 V in the dark under various temperatures, in accordance with an exemplary embodiment of the present disclosure.

FIG. 50B shows a plot of current (A) versus temperature (K), representing dark current output for an example substrate comprising p-Si/ZnO in the dark under various temperatures at −2 V, in accordance with an exemplary embodiment of the present disclosure.

FIG. 50C shows a plot of current (A) versus voltage (V) of an example substrate comprising p-Si/ZnO from −1.9 to −1 in the dark under various temperatures, in accordance with an exemplary embodiment of the present disclosure.

FIG. 50D shows a plot of current (A) versus temperature (K), representing dark current output for an example substrate comprising p-Si/ZnO in the dark under various temperatures at 1.9 V, in accordance with an exemplary embodiment of the present disclosure.

FIG. 51A shows a plot of current (A) verses voltage (V) of an example substrate comprising p-Si/ZnO from −2 to 0 V under illumination under various temperatures, in accordance with an exemplary embodiment of the present disclosure.

FIG. 51B shows a plot of current (A) verses temperature (K⁻¹), representing photocurrent output for an example substrate comprising p-Si/ZnO in the dark under various temperatures at −2 V, in accordance with an exemplary embodiment of the present disclosure.

FIG. 51C shows a plot of current (A) verses voltage (V) of an example substrate comprising p-Si/ZnO from −1.9 to −1.0 V under illumination under various temperatures, in accordance with an exemplary embodiment of the present disclosure.

FIG. 51D shows a plot of current (A) verses temperature (K⁻¹), representing photocurrent output for an example substrate comprising p-Si/ZnO in the dark under various temperatures at −1.9 V, in accordance with an exemplary embodiment of the present disclosure.

FIG. 52A provides a plot the trigger time of positive photocurrent and negative photocurrent under different temperatures, in accordance with an exemplary embodiment of the present disclosure.

FIG. 52B provides a plot of the fall time of positive photocurrent (black) and negative photocurrent (blue) under different temperatures, in accordance with an exemplary embodiment of the present disclosure.

FIG. 52C provides a plot of the charge transferred between electrodes due to the alternating current photo-response under different temperatures, in accordance with an exemplary embodiment of the present disclosure.

FIG. 52D provides Arrhenius plots of fall time vs. temperatures, in accordance with an exemplary embodiment of the present disclosure.

FIG. 53 provides a plot of current (μA) versus time (ms) (I-t) representing a typical response of an AC photocurrent and the definition of trigger time and fall time, in accordance with an exemplary embodiment of the present disclosure. Trigger time is the time for the signal to increase its output from 10% to 90% of the peak level. The fall time is the time it takes for the detector to decrease from 90% of the peak value to a value equal to 10% of the final output. The fall times of positive current is marked as fall time (+) and negative current marked as fall time (−).

### DETAILED DESCRIPTION

To facilitate an understanding of the principles and features of the present disclosure, various illustrative embodiments are explained below. The components, steps, and materials described hereinafter as making up various elements of the embodiments disclosed herein are intended to be illustrative and not restrictive. Many suitable components, steps, and materials that would perform the same or similar functions as the components, steps, and materials described herein are intended to be embraced within the scope of the disclosure. Such other components, steps, and materials not described herein can include, but are not limited to, similar components or steps that are developed after development of the embodiments disclosed herein.

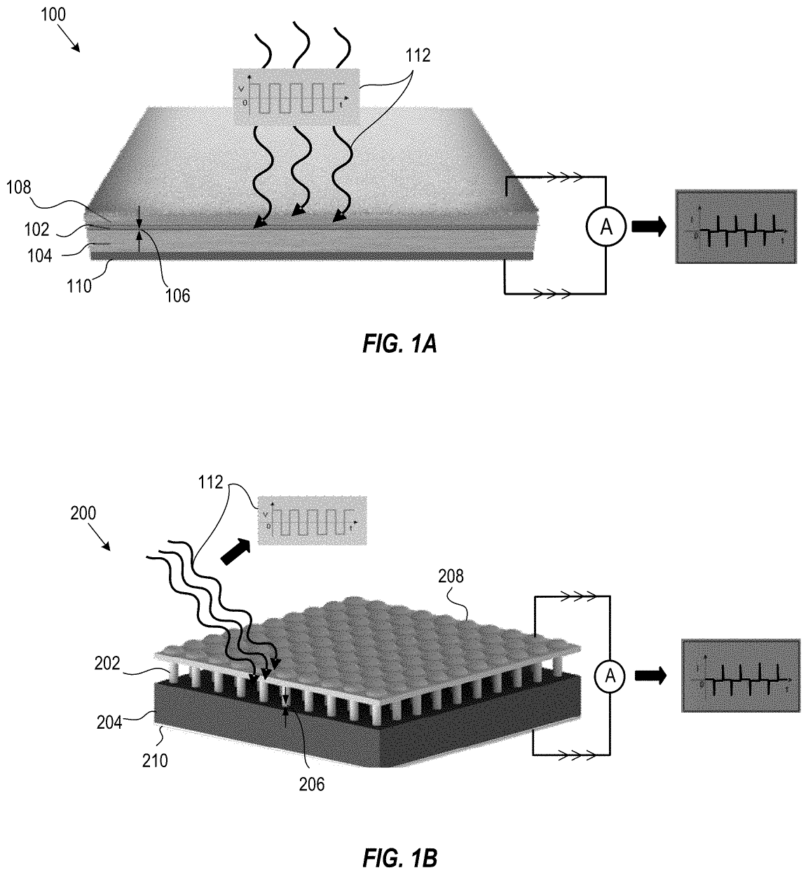

As shown in FIG. 1A, an exemplary embodiment of the present invention provides a substrate 100 for generating alternating current (AC) under periodic light. In some embodiments, substrate 100 can be a device that can convert light into electricity using semiconductors that exhibit a photovoltaic effect. For instance, substrate 100 can be a photovoltaic device, a solar cell, a solar module, a grid-connected PV system (e.g., rooftop PV system or building-integrated photovoltaic system), a concentrator photovoltaic, a multi-junction solar cell, a photovoltaic thermal hybrid solar collector, a thin-film solar cell, an agrivoltaic, a charging station, a floatovoltaic, a solar vehicle (e.g., solar cars, solar aircrafts, etc.), a low power transmitter, a heterogeneous combustor, or the like. In some embodiments, substrate 100 can be a device that can convert light into current such as a photosensor, a photodetector, a photodiode, and/or a photo transistor, or the like.

Referring back to FIG. 1A, substrate 100 can comprise a first material 102 abutting a second material 104, forming an interface 106. Materials can include pure conductive elements or intrinsic (i-type) and undoped materials (e.g., silicon, germanium, selenium, tellurium, gray tin, carbon), binary materials (e.g., gallium arsenide, gallium nitride, gallium phosphide, gallium antimonide, boron nitride, boron phosphide, boron arsenide, aluminum nitride, aluminum phosphide, aluminum arsenide, aluminum antimonide, indium nitride, indium phosphide, indium arsenide, indium antimonide, cadmium selenide, cadmium sulfide, cadmium telluride, zinc selenide, zinc sulfide, zinc telluride, cuprous chloride, copper sulfide, lead selenide, lead(II) sulfide, lead telluride, tin(IV) sulfide, tin telluride, and silicon carbide), tertiary materials (lead tin telluride, thallium tin telluride, thallium germanium telluride, barium titanate, strontium titanate, lithium niobate, lanthanum copper oxide), quaternary materials (e.g., copper zinc tin sulfide (CZTS), copper zinc tin sulfide selenide (CZTSSe), copper zinc antimony sulfide (CZAS), copper tin sulfide (CTS), and copper indium gallium sulfide (CIGS), etc.), oxides and alloys (titanium dioxide, copper oxide, uranium dioxide, bismuth trioxide, tin dioxide, vanadium oxide, hematite, and zinc oxide), and organic semiconductors (e.g., acenes, rubrenes, and triphenylenes), including polymer semiconductors (e.g., molecularly doped polycarbonate, poly-thiophene, poly-phenyleveninylene, and poly(carbazole-dithiophene-benzothiadiazole (PCDTBT)). Certain embodiments provide for crystalline solid semiconducting materials, but amorphous and liquid semiconductors are also contemplated.

Semiconducting materials can include a wide range of energy level bandgaps ranging from about 0.1 eV to about 7.8 eV and can absorb photons with wavelengths ranging from about 4 μm (infrared) to about 10 nm (deep ultraviolet). Intrinsic semiconductors, also referred to as i-type semiconductors, comprise pure and undoped semiconductors. Semiconducting materials can also be doped with trace electron donor dopant atoms (n-type) or electron acceptor dopant atoms (p-type) to modulate the energy level bandgap. In some embodiments, semiconductor materials can be intentionally doped to augment the electrical, optical, and/or structural properties of a material.

In some embodiments, first material 102 can form interface 106 with the same material composition having a different concentration of charge carriers. For example, silicon is a purely intrinsic semiconductor material that can form an interface with a second silicon material having more or less charge carriers when the second silicon material is doped with an electron donor dopant or an electron acceptor dopant. As would be appreciated by those of skill in the relevant art, the same material composition can also include the same doping-type that forms an interface between the same materials having different concentrations of charge carriers. For example, an n-type silicon can form an interface with a n⁺-type silicon, or a highly doped silicon, such that the first n-type silicon has a different concentration of charge carriers than the n⁺-doped silicon material.

In any of the embodiments disclosed herein, first material 102 can form interface 106 with a different material composition. For example, an n-type material such as titanium dioxide can form an interface when abutting a p-type material such as p-doped silicon and generating a p-n junction. Certain embodiments further provide a third material forming interface 106 with first material 102 and second material 104. A third material can comprise a layer of intrinsic semiconductor or insulator layer between first material 102 and second material 104 such that the third material can be within interface 106 of first material 102 and second material 104. As would be appreciated, interface 106 can comprise a p-n junction, an n-p junction, a p-insulator-n junction, a p-intrinsic-n junction a p-p⁺ junction, a n-n⁺ junction, or a series of junctions (e.g., p-n-p-n . . . -n) having a different concentration of charge carriers.

In some embodiments, first material 102 can comprise a first electrode 108, while second material 104 can comprise a second electrode 110. First electrode 108 and second electrode 110 can contact the respective first and second materials 102, 104 and form a circuit. First and second electrodes 108, 110 can function to output current generated from substrate 100 exposed to periodic light stimulation. In some embodiments, first and second electrodes 108, 110 can comprise the same electrode materials. In any of the embodiments herein, first and second electrodes 108, 110 can comprise different electrode materials. First and second electrodes 108, 110 can each be any metal or alloy commonly used for electrical purposes, such as copper, graphite, titanium, brass, silver, platinum, palladium, gold, iron, nickel, lead, magnesium, aluminum, tin, zinc, mixed metal oxides (e.g., indium-tin-oxide (ITO), indium-zinc-oxide, etc.), and the like.

Certain embodiments disclosed herein provide for a voltage bias to be applied to substrate 100 from first electrode 108 and second electrode 110. In some embodiments, no bias voltage is applied and substrate 100 can generate alternating current (AC) under periodic light stimulation. In some embodiments, a small voltage is applied. The small voltage can range from about 0 V to about 0.2 V, but is not limited to these values (e.g., from about 1 pV to about 1 nV, from about 1 nV to about 0.01 V, from about 0.01 V to about 0.1 V, from about 0.1 V to about 0.2 V, and any range in between, e.g., 0.08 V to about 0.13 V). In some embodiments, small applied voltage can indicate that the dark current is kept at a very low value in order to generate AC from substrate 100 when substrate 100 is not exposed to light stimulation. In some embodiment, the small bias voltage means the dark current at the applied voltage is extremely low and can range from several microamperes (mA) to several picoamperes (pA). In some embodiments, substrate 100 can generate AC under periodic light stimulation when a bias voltage from 0 V to about 0.2 V is applied.

In some embodiments, substrate 100 can be a simple substrate having two dissimilar materials forming interface 106 as shown in FIG. 1A; however, example embodiments of the present disclosure provide for more complex substrates, such as substrate 200 shown in FIG. 1B. As shown, substrate 200 can comprise a first material 202, such as a nanowire pillar comprising any of the materials described above. In some embodiments, the nanowire pillar can be a metal oxide (e.g., titanium dioxide, copper oxide, uranium dioxide, bismuth trioxide, tin dioxide, vanadium oxide, hematite, and zinc oxide) grown into pillars on second substrate 204, or on an insulator material. It should be understood that first material 202 is not limited to being a pillar structure but can form any shape in any dimension such that first material 202 is contacting second material 204 and forming interface 206. First material 202 can further be contacting a first electrode 208 and second material 204 can be contacting a second electrode 210. Similar to FIG. 1A, interface 206 can comprise a p-n junction, an n-p junction, a p-insulator-n junction, a p-i-n junction a p-p⁺ junction, a n-n⁺ junction, or a series of junctions (e.g., p-n-p-n . . . -n) having a different concentration of charge carriers.

Certain embodiments of the present disclosure provide substrate 100, 200 that generates current under light stimulation. When substrate 100, 200 is exposed to continuous light stimulation, a direct current (DC) can be generated and stored in a battery. Direct current is the conventional electricity generated from a photovoltaic device under conventional continuous light stimulation; however, the systems and methods described herein can generate either DC or AC. In some embodiments and as shown in FIGS. 1A and 1B, substrate 100, 200 can generate AC under periodic light stimulation 112.

In some embodiments, periodic light stimulation 112 can be directed to contact substrate 100, 200 at interface 106, 206, where different concentrations of charge carriers exist. A light source can provide wavelengths of light ranging from deep ultraviolet light (from about 20 nm to about 400 nm), visible light (from about 400 nm to about 750 nm) and to infrared light (from about 750 nm to about 3 μm). Periodic light stimulation 112 can be made non-continuous in a number of ways, including blocking a continuous light path such that substrate 100, 200 is exposed to a non-continuous and periodic stimulation from a light source and/or modulating the light source by a function generator to provide incoming light in various waveforms.

In some embodiments, blocking of a continuous light path can be done manually or automatically. In some embodiments, an external component, either solid or semi-solid, may be adjusted to move within the continuous light path and prevent the continuous light path from reaching substrate 100, 200. For example, an external optical chopper system, chopper wheel, or a rotating component can be added to the systems described herein. In some embodiments, a shutter over a light source may be opened and closed at a specific rate in order to periodically block a continuous light path. Methods other than a high-speed optical chopper and/or shutter system are contemplated for blocking a continuous light path from substrate 100, 200. Periodic light stimulation 112 reaching substate 100, 200 and interface 106, 206 can have a frequency ranging from about 0.1 Hz to about 1 GHz, such that photons from periodic light stimulation 112 can sufficiently excite electrons and generate excess charge carriers in transition states. Such excess charge carriers in transition states can lead to a Fermi level shift within substrate 100, 200 and generate AC.

Another method to make periodic light stimulation 112 non-continuous includes adjusting the power or waveform of a light source using a function generator or waveform generator. Waveforms can include, but are not limited to a square waveform, a rectangular waveform, a sinusoidal waveform, a triangular waveform, a sawtooth waveform, a step waveform, a pulsed waveform, and the like. As would be appreciated by those of skill in the relevant art, additional waveforms and non-uniform waveforms can also be used to generate periodic light stimulation 112.

In any of the embodiments disclosed herein, the systems of methods can be used for any application requiring alternating current. Applications of alternating current are so vast, as most electrical devices and appliances that are plugged into an outlet rely on AC for power. Some example devices and appliances can include, for example, electrical motors, refrigerators, dishwashers, desktop computers, televisions, and the like. It is contemplated that systems and methods of the present disclosure can also be applied as AC generators, sensors, photodiodes, solar cells, and wireless power sources.

The following examples further illustrate aspects of the present disclosure. However, they are in no way a limitation of the teachings or disclosure of the present disclosure as set forth herein.

### EXAMPLES

It is well known that the photovoltaic effect produces a direct current (DC) under solar illumination owing to the directional separation of light-excited charge carriers at the p-n junction, with holes flowing to the p-side and electrons flowing to the n-side. Here, the inventors discovered that, except the DC generated by the conventional p-n photovoltaic effect, there is another new type of photovoltaic effect that generates alternating current (AC) in the non-equilibrium states when the illumination light is periodically shining at the junction/interface of materials. The peak current of AC power at high switching efficiency could be much higher than that from DC. The AC cannot be explained by the established mechanisms for conventional photovoltaics, instead, it is suggested owing to the relative shift between the quasi-Fermi levels of the semiconductors adjacent to the junction/interface under the non-equilibrium conditions, which results in an electron flow in the external circuit back and forth to balance the potential difference between the electrodes. By virtue of this effect, the device could be a high-performance broadband photodetector with extremely high sensitivity under zero bias; and they could also work as a remote power source providing extra power output in addition to the conventional PV effect.

It is highly desirable to discover renewable and clean energy for sustainable development of human civilization. Photovoltaic (PV) effect has been widely investigated in solar cells as a sustainable energy source to replace fossil fuels. The conventional photovoltaic effect based on p-n junction model converts light energy directly into electricity via processes of light absorption, carrier excitation, hole/electron separation, charge transport, and recombination. Owing to the separation of the holes and electrons by a built-in potential at the junction/interface, it naturally provides a direct current (DC) output. There are some other mechanisms to generate voltage and electric current in a material upon exposure to light. The Dember effect is generated when photoexcited electrons and holes have different mobilities; thus, there is a potential difference between the illuminated and non-illuminated areas in a homogeneous limited semiconductor. A single crystal with a non-centrosymmetric structure exhibits the bulk photovoltaic effect that under uniform illumination, an anomalously large photovoltage originates from the different probabilities for photoexcited carrier motion in one direction versus the opposite direction, caused by the absence of centrosymmetry in the material. Photoelectric current can also be produced by photon-drag effect, that the momentum carried by electromagnetic waves is transferred to the charge carriers during interband or intraband energy transitions, leading to the ordered motion of the carriers relative to the lattice in the direction of light propagation. Becquerel photovoltaic effect has also been explored at a semiconductor-electrolyte interface for the conversion of radiant energy to electrical and/or chemical energy.

### Example 1: Alternating Current (AC) from Periodic Light Stimulation

Here, by surprise, it was found that an alternating current (AC) is produced if a light is incident upon the interface/junction of two materials periodically. When the device based on a p-Si/n-TiO₂ nanofilm was under illumination of a flashing light at 442 nm with 7.79 mW/cm², the peak of the AC could reach 236 μA, and the peak of voltage of the AC output could reach more than 20 mV. This means that the observed current oscillates back and forth in the external circuit in responding to the flashing of light. This phenomenon is new, and it cannot be explained by the established photovoltaic mechanisms in literature. The system is rather unique and different in the following aspects. In contrast to the conventional photovoltaic effect and thermoelectric effect, it generates an AC instead of DC. The device uses non-piezoelectric materials, the output characteristics are dissimilar to those of either piezoelectric effect for converting mechanical energy into electric power or pyroelectric effect. The device has no moving part in responding to direct mechanical triggering, so that the AC produced is not created by the triboelectric effect. Additionally, the AC does not follow the Ohm's law, instead it is based on Maxwell's displacement current model. A relative shift in quasi-Fermi levels for the materials adjacent to the junction/interface in response to the excitation and thermal effect of the illumination light under non-equilibrium conditions was found. This new effect provides a novel approach to detect a wide wavelength range of light, and it has ultra-high sensitivity of light detection even at ultra-low light intensity. The system could be also used as a remote wireless power source for powering boost the output of photocells for powering small-scale electronic devices. The devices are simple, low cost, easy-fabrication, and could be easily integrated into silicon-based circuits.

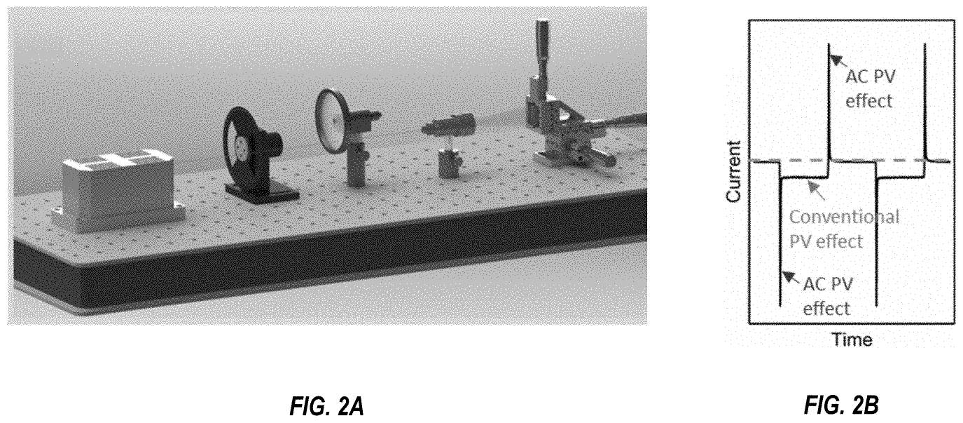

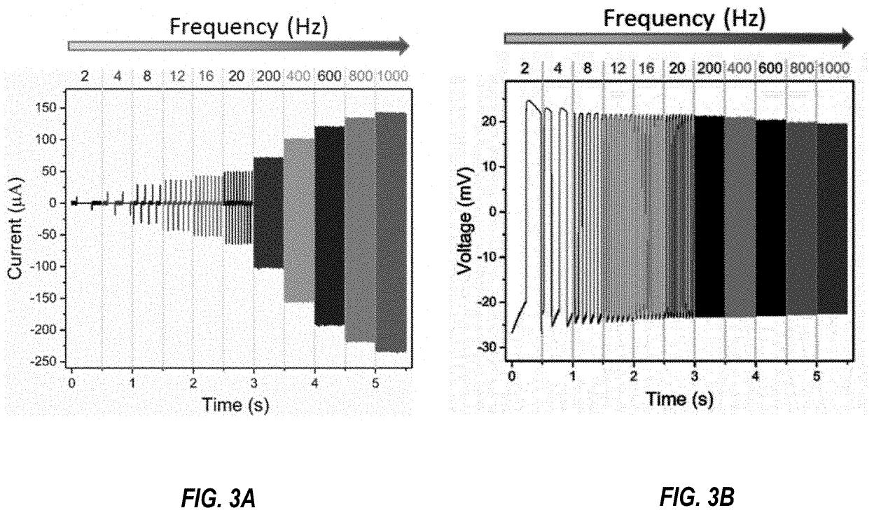

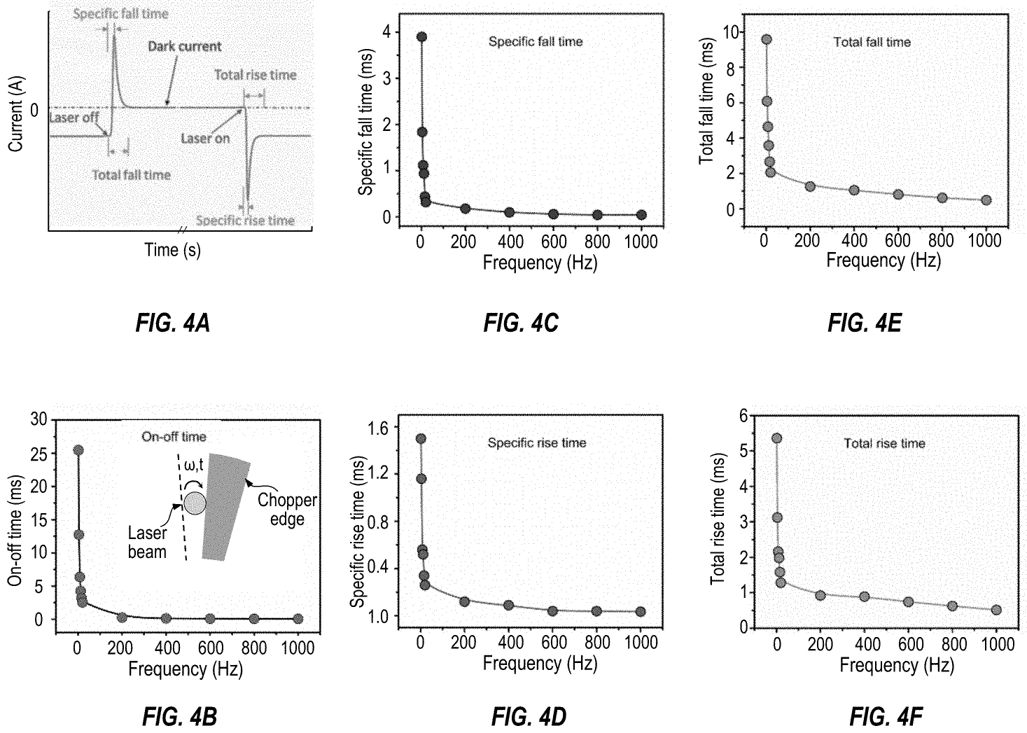

A device based on p-Si/TiO₂ nanofilm junction was studied as an example substrate. A 15 nm thickness of TiO₂ was deposited on the pre-washed p-Si substrate via atomic layer deposition (ALD). The Al and indium tin oxide (ITO) are acted as the two electrodes at the p-Si and TiO₂ sides respectively. The active area of the device is about 0.8 cm×0.8 cm. The measurement was set up under an illumination of a 442 nm wavelength laser and an optical chopper was positioned to regulate the light switching on and off at a fixed frequency (FIG. 2A). An objective lens was used to expand the laser when necessary. A high sampling rate is needed to record the signals, which is set as 10⁵ samples per second. When the chopper rotates, the device generates an AC. FIG. 2B shows that the typical signals from the device have AC components and DC components. Under the thermal equilibrium conditions that light is kept either on or off, there are two flat regions (DC current) in which the one close to 0 A is the dark current, and the other one is the photocurrent that is caused by the conventional photovoltaic effect. When the chopper rotating speed is high enough, the flat regions would be cut down due to the short cycling time. The peaks of the AC are much higher than the output of the DC component. AC is produced only under the non-thermal equilibrium conditions that when the light is switched from off to on, the signal shows a trough followed with a flat photocurrent; when the light is switched from on to off, the output signal has a peak, then followed by a dark current. The output value is strongly correlated to the chopper's rotating frequency. As shown in FIG. 3A, with the increase of the working frequency from 2 to 1,000 Hz, the negative short-circuit current I_{SC} rises from 10 to 236 μA. The negative current is superposition of two signals from both AC and DC, while the positive current is only from AC. Concerning the mechanism of this effect, the open-circuit voltage V_{oc} of the AC output was also measured by using the AC mode of a low-noise voltage preamplifier. FIG. 3B shows that as the frequency increases, the V_{oc} of the AC output is relatively stable, despite a slightly declining trend that is seen from −27.1 to −22.5 mV. FIGS. 3A and 3B show that as the frequency increase, the current increases while the voltage slightly drops, which demonstrates that the relationship of AC current and voltage does not follow Ohm's law. This is referred to as a capacitive conduction model rather than a resistive conduction model, in which the Maxwell's displacement current is the conduction mechanism for electricity transport. By integration of the current curve with respect to time, the total charges transferred in the AC part each cycle (from 2 to 800 Hz) remain almost the same which are about 22 nC, and only slightly decrease about ˜10% at high-frequency rate (800-1,000 Hz), this may because not all the charges are able to transfer in a short cycling time. It is notable that with increasing frequency, the time for the light to transit from completely on to fully off plummets initially and then gradually reduces at higher frequencies, as shown in FIGS. 4A-4F. By definition, current is the rate of flow of charge: I=ΔQ/Δt. So, while the charges remain almost the same, a significantly shorter transit time leads a much larger current output.

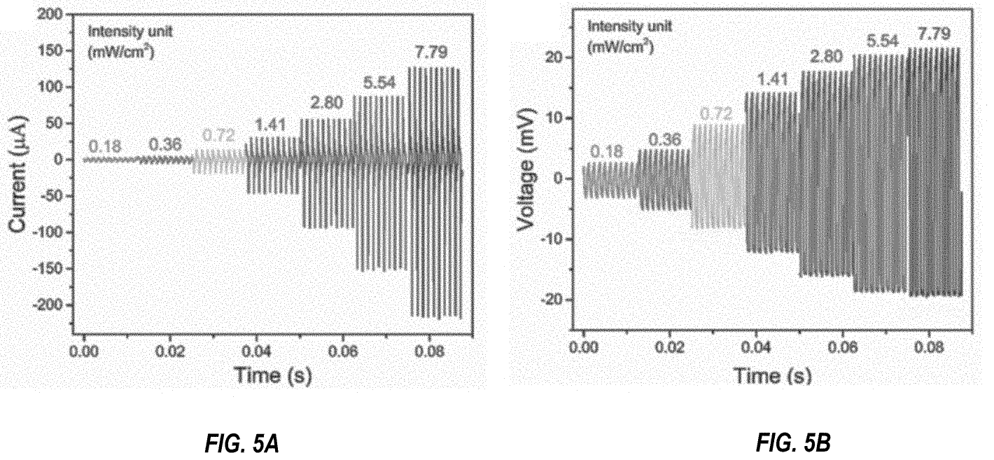

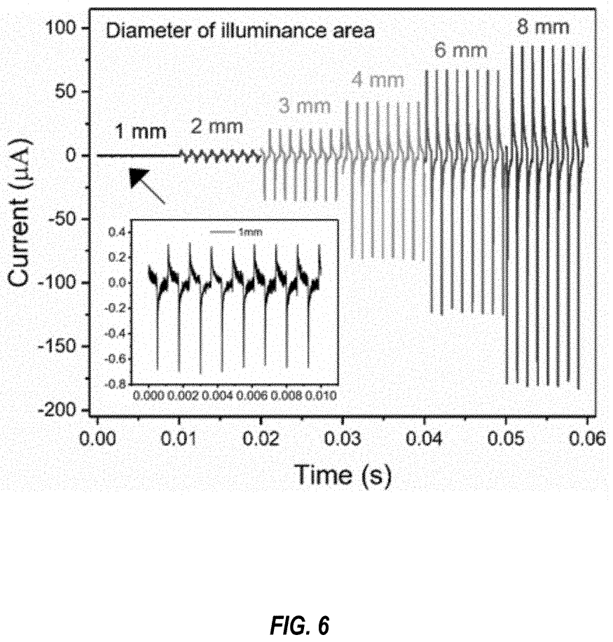

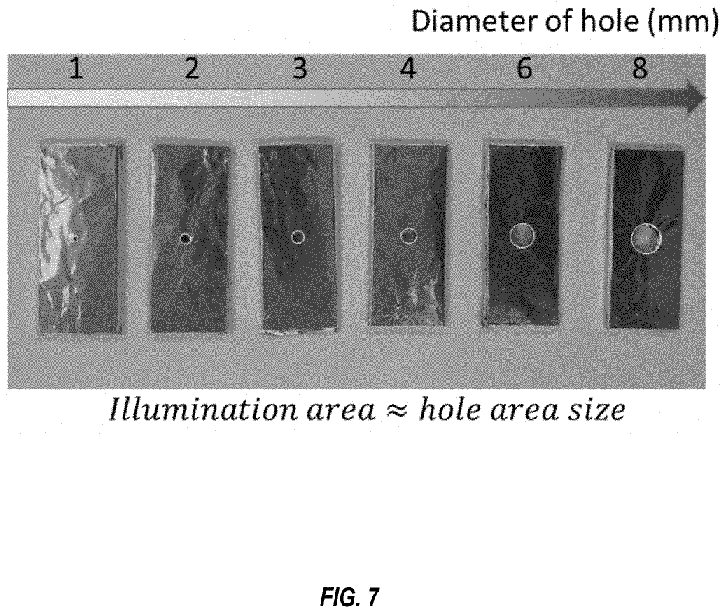

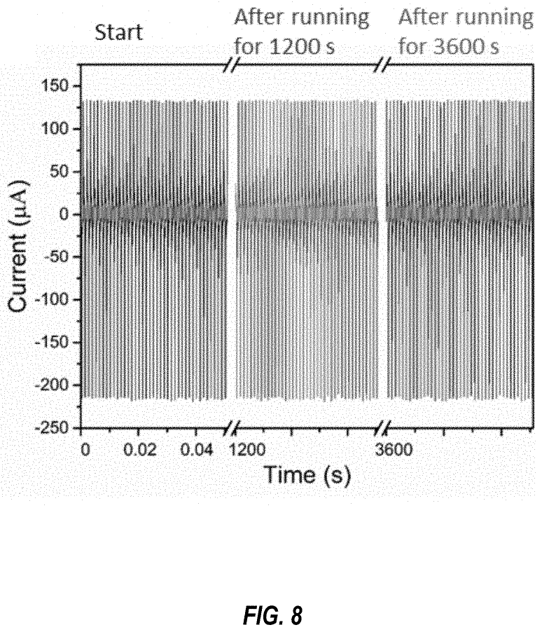

The magnitude of the current and voltage are also strongly related to light intensity. As the intensity increases from 0.18 to 7.79 mW/cm², the maximum current increases from −2.95 to −219 μA (FIG. 5A) and the maximum voltage increases from −3.18 to −21.53 mV (FIG. 5B) at a frequency of 800 Hz. This reveals that the electrical output is strongly associated with light absorption and total amount of light excited charge carries. This is further illustrated by the results in FIG. 6. Acrylic plates covered with aluminum foil were placed in front of the device. Holes ranging from 1 to 8 mm in diameter were cut by laser cutter in the center of the acrylic plates to control the illumination area. The beam was expanded, and the output was measured under the same illumination condition at 800 Hz. FIG. 6 shows that as the diameter increases from 1 to 8 mm, the maximum current increases from −0.72 to −185 μA. The stability and repeatability studies are presented in FIG. 8. The device was subject to the working conditions for about 2 hours with more than 3.6 million cycles, the output signals have no deviation nor degradation at all.

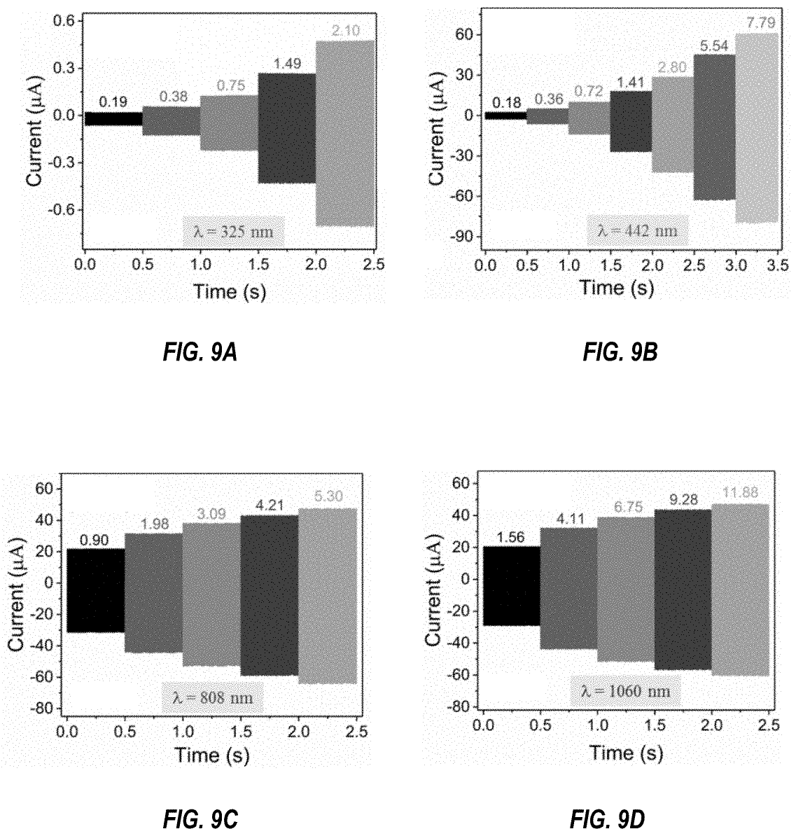

Not restricted to visible light of 442 nm wavelength, various wavelengths of lights are also able to produce the AC signals, as shown in FIGS. 9A-9D. At different wavelengths of light ranging from ultraviolet (325 nm) to near-infrared (1,060 nm) at a chopper rotating frequency of 1,000 Hz, the device generates AC and the output values increase as the light intensity increases. With this effect, the device demonstrates a broadband response to a variety of light wavelengths, and the AC current is excited even when the exciting photon energy is below the bandgap.

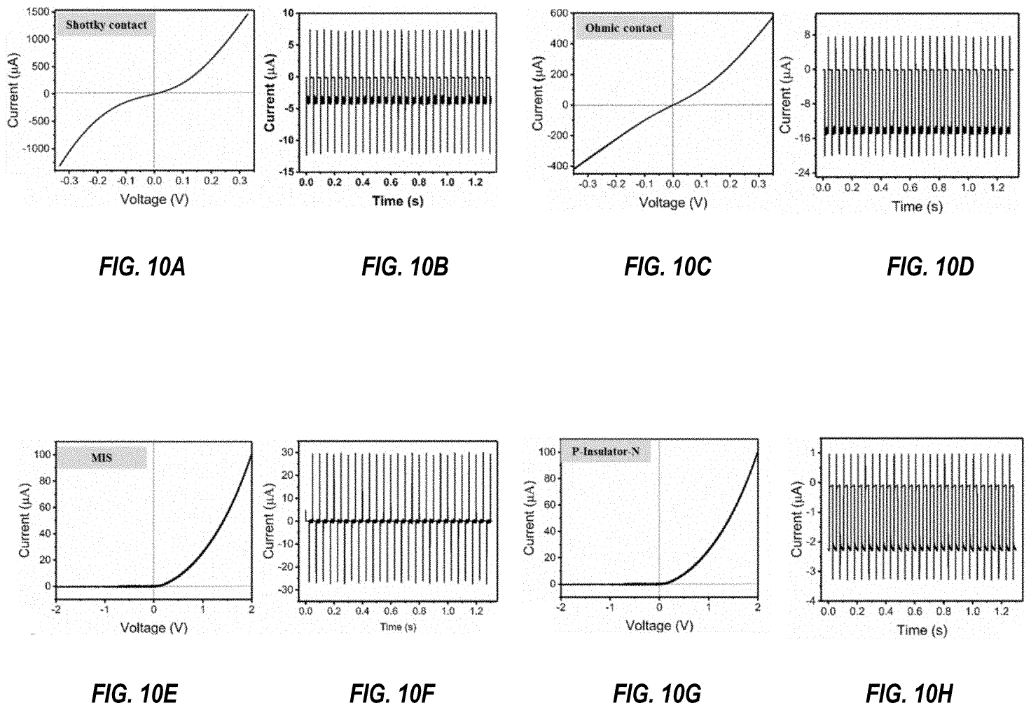

The above illustrated phenomenon is rather universal and has also been observed for other typical types of junctions, including Schottky contact (Al/p-Si/ITO), Ohmic contact (ITO/p-Si/ITO), Metal-Insulator-Semiconductor (MIS, p-Si/AlOₓ/ITO), and P-Insulator-N(PIN, p-Si/AlOₓ/ZnO). The details of the fabrication process are described in Methods and previous work. Briefly, a 200 nm thickness of Al and 100 nm of ITO were deposited as the electrodes via electron-beam evaporator and physical vapor deposition. The insulator layer AlOₓ was deposited via atomic layer deposition (ALD). FIGS. 10A-10H show current-voltage characteristics of the junctions in dark compared to current-time characteristics under the illumination of 442 nm light at a frequency of 20 Hz. These results reveal that this effect is universal and assuredly exists in a variety of junctions under the working conditions.

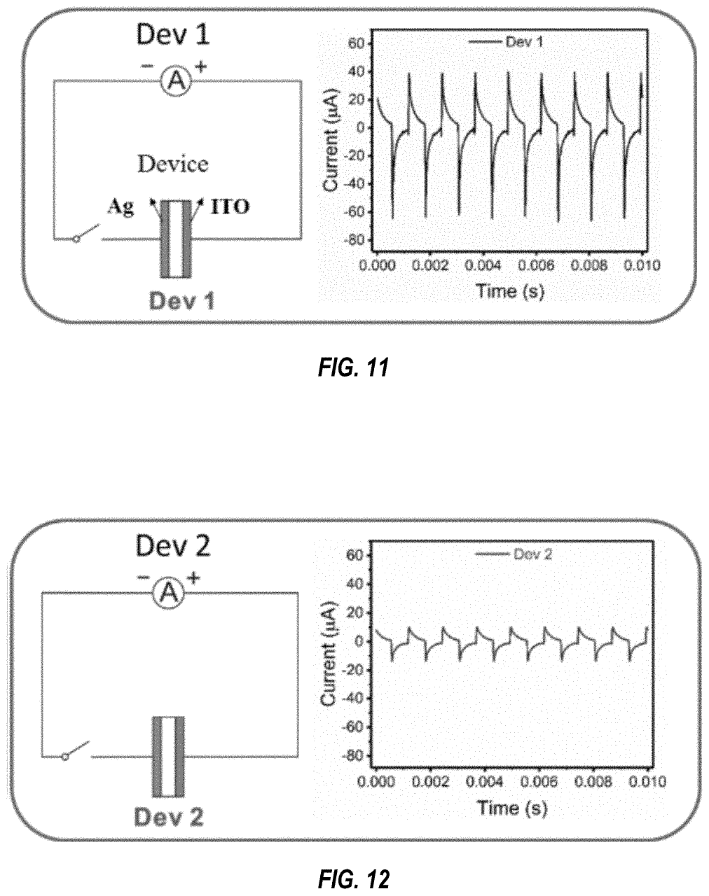

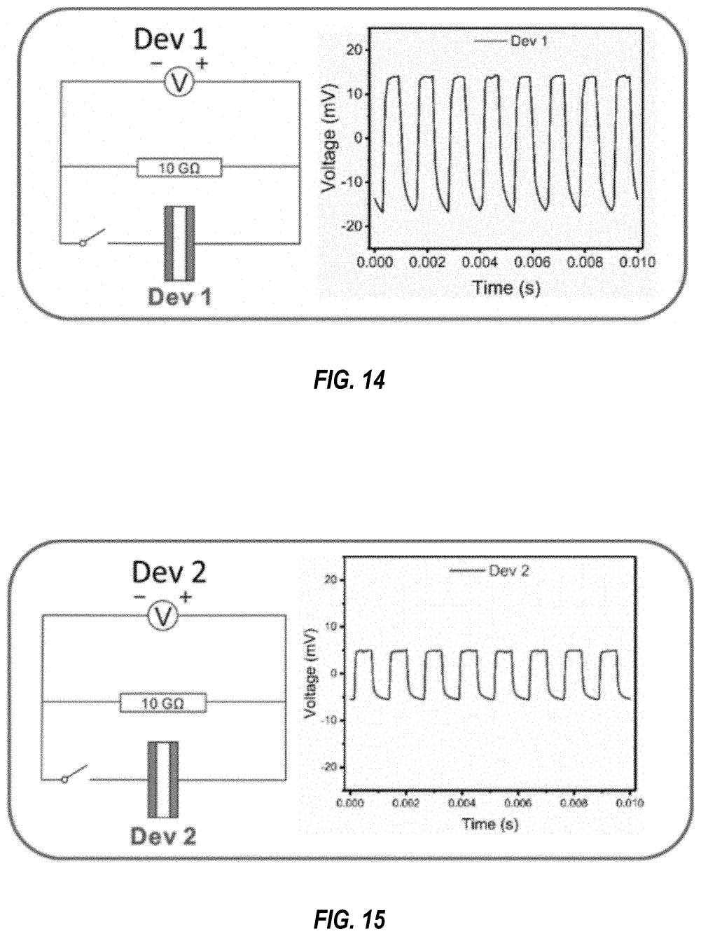

The observed phenomenon is undoubtedly a true effect. As demonstrated, the output current is highly dependent on light intensity, chopper frequency and illumination area. To further verify that the measured signals are indeed generated by the device, a number of ‘linear superposition’ tests have been conducted (FIGS. 11-16).

### Example 2: Mathematical Analysis and the Change of Parameters During the Whole Cycle

For a mathematical analysis, we adopt a one-dimensional analysis since the lateral dimensions are much larger than the vertical ones. First, the Poisson equation relates the electric potential to the electric charge:

$$\frac{d}{d x} ( {ϵ}_{( x )} \frac{d V ( x )}{d x} ) = - ρ ( x ) , \qquad \# ( S5 )$$

where x is the coordinate, V(x) is the electric potential, ρ(x) is the charge density in the space charge region, and ∈₍ₓ₎ is the dielectric permittivity of the semiconductor.

To understand non-equilibrium excess carriers in semiconductors, the continuity equations for electrons and holes is listed as following:

$$\begin{matrix}\frac{\partial n}{\partial t} = \frac{1 {dJ}_{n}}{e d x} + {G}_{n} - {R}_{n} , & \# ( S6a ) \\ \frac{\partial p}{\partial t} = \frac{1 {dJ}_{p}}{e d x} + {G}_{p} - {R}_{p} , & \# ( S6b )\end{matrix}$$

where n (or p) is the electron (or hole) density, Jₙ (or Jₚ) is the electron (or hole) current density, Gₙ (or Gₚ) is the net electron (or hole) generation rate per unit volume, Rₙ (or Rₚ) is the net electron (or hole) recombination rate per unit volume, and e is the absolute value of the electron charge. To simplify, only drift and diffusion are considered, the electron and hole currents are typically expressed as follows:

$$\begin{matrix}{J}_{n} = - e {μ}_{n} n \frac{d V}{d x} + e {D}_{n} \frac{d n}{d x} , & \# ( S7a ) \\ {J}_{p} = - e {μ}_{p} n \frac{d V}{d x} + e {D}_{p} \frac{d p}{d x} , & \# ( S7b )\end{matrix}$$

where μₙ (or μ_{P}) is the electron (or hole) mobility and Dₙ (Dₚ) is the electron (hole) diffusion coefficient. Since the intrinsic Fermi level follows changes in the electric potential,

$$\frac{d {E}_{Fi}}{d x} = - \frac{e d V}{d x} , \qquad \# ( S8 )$$

and combine the equation (2) and (3), the equation (S7a), (S7b) are reduce to the compact form:

$$\begin{matrix}{J}_{n} = {μ}_{n} \frac{d {F}_{n}}{d x} , & \# ( S9a ) \\ {J}_{p} = {μ}_{p} \frac{d {F}_{p}}{d x} , & \# ( S9b )\end{matrix}$$

For a semiconductor, if free electron-hole pairs are generated, Fₙ moves upwards whereas Fₚ moves downwards in the bandgap. This would lead to generate current, and the energy difference (Fₙ−Fₚ) represents the deviation from the original equilibrium state.

Low injection, or low-level injection, means that the excess carrier concentration is much smaller than the thermal-equilibrium majority carrier concentration. For example, low injection in the p-type semiconductor implies that Δₚ<<p₀.

At any T>0° K, electrons are continually being thermally excited from the valence band into the conduction band by the random nature of the thermal process. At the same time, electrons moving randomly through the crystal in the conduction band may come in close proximity to holes and “fall” into the empty states in the valence band. This recombination process annihilates both the electron and hole. At thermal equilibrium, the concentrations of electron and hole are constant, thus the rate at which electrons and holes are generated and the rate at which they recombine are equal:

Gₙ₀=Gₚ₀=Rₙₒ=Rₚ₀

where Gₙ₀ and Gₚ₀ are the thermal-generation rates of electrons and holes, Rₙ₀ and Rₚ₀ are the recombination rates of electrons and holes respectively.

When high-energy photons are incident on a semiconductor, electron-hole pairs (Δₙ, Δₚ) are generated, the concentration of electrons in the conduction band and of holes in the valance band increase above their thermal equilibrium value. At the time low-injection just introduces, the generation rate of electron-hole pair significantly raises, the recombination rate still remains the same at the beginning and start to grow. Carriers are generated faster than they recombine, the electrons and holes start to accumulate, but the materials respond to the generation of excess carriers by increasing the recombination rate, attempting to turn the system into a new equilibrium.

Until the light is fully on, the illumination is stable, a steady-state generation of excess electrons and holes will not cause a continual buildup of the carrier concentrations. In this new thermal equilibrium condition, the recombination rate for excess electrons Rₙ′ and for excess holes Rₚ′ must be equal, the generation and recombination of electron-hole pairs are equal.

Reversely, when the light switches to off, the opposite phenomena takes place, the system has to return to the original state. When the light switches from off to on, at first, the recombination rate remains the same, the generation rate of the light-induced excess carriers is decreasing significantly. As the concentration of holes and electrons are decreasing below this new thermal equilibrium value, the recombination rate starts to decrease. Finally, the system returns to the initial thermal equilibrium state when the recombination rate equals the generation rate again.

In analyzing these processes, the recombination rate of excess electrons and holes are given by:

$$R ≡ {R}_{n} = {R}_{p} = \frac{{C}_{n} {C}_{p} {N}_{L} ( n p - {n}_{i}^{2} )}{{C}_{n} ( n + {n}^{′} ) + {C}_{p} ( p + {p}^{′} )} \qquad \# ( S11 )$$

where Cₙ is a constant proportional to the probability of the trap capturing an electron, and Cₚ is a constant proportional to the probability of the trap capturing a hole. The parameter Nₜ is the density of traps, and the parameters n′ and p′ are given by

$$\begin{matrix}{n}^{′} = {N}_{C} exp [ \frac{- ( {E}_{C} - {E}_{t} )}{k T} ] & \# ( S12a ) \\ {p}^{′} = {N}_{v} exp [ \frac{- ( {E}_{t} - {E}_{v} )}{k T} ] & \# ( S12b )\end{matrix}$$

When the low injection introduces, the system then is in non-equilibrium due to the excess carriers are generated, which causes the changes of parameters.

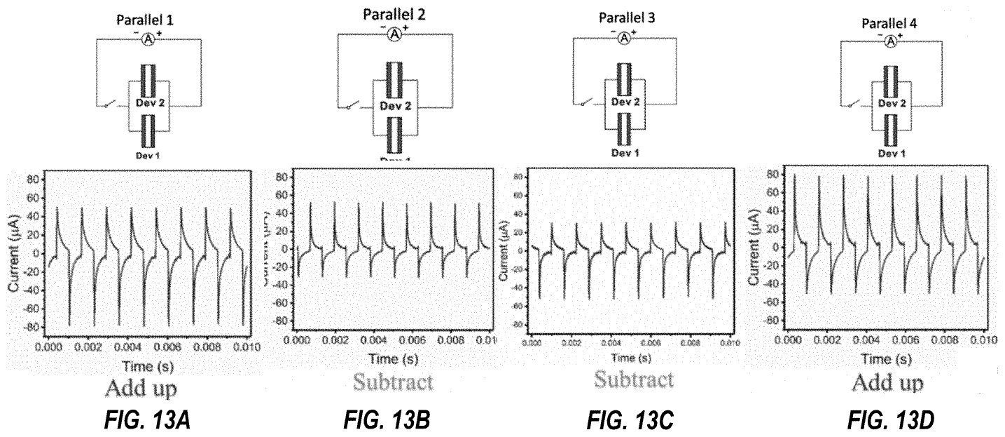

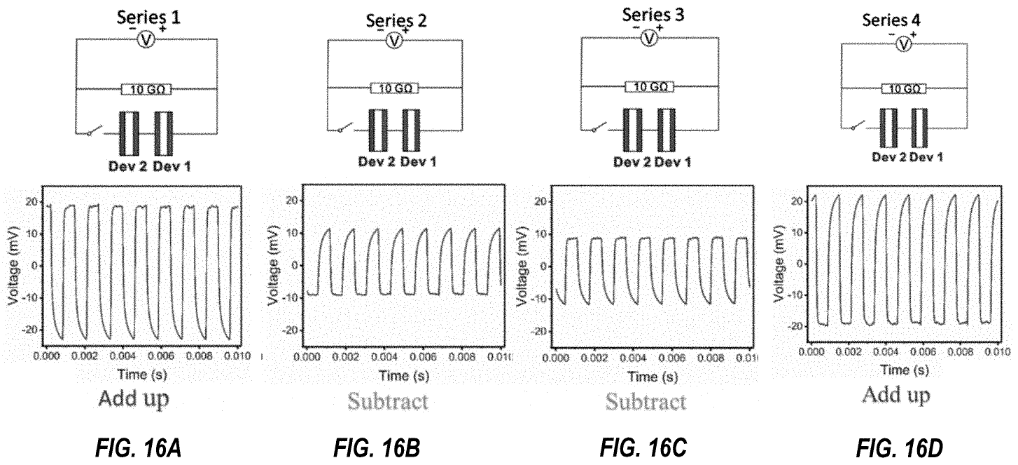

The laser beam was expanded by an objective lens, and the intensity distribution of the laser beam followed a Gaussian distribution. Two p-Si/TiO₂ devices were placed at different positions with different light intensity so the electric output values are different. Both the short-circuit current (I_{sc}) and open-circuit voltage (V_{oc}) of each linear element device 1 and 2 (labeled as Dev 1 and Dev 2) were measured independently (FIGS. 11, 12, 14, and 15). When the two electrodes of the devices are connected in reverse with the electrometer, the voltage and current pulses should be also reversed by reverting the sign. By comparing the results from experimental groups of (FIGS. 13A and 13D), (FIGS. 13B and 13C), (FIGS. 16A and 16D), (FIGS. 16B and 16C), when two devices were connected in reverse to the measurement system, the output values of current and voltage were reversed respectively. The ‘switching polarity test’ proves that the signals are from the devices themselves, since the signals would remain the same even when the polarity is switched if they come from noise or the environment. All eight types of connection methods for two devices in both parallel and series models are illustrated in FIGS. 11-16. From the linearity theorem, when two devices are connected in parallel, the measured current equals the algebraic sum of the current response caused by each independent source; when in series, the measured voltage equals the sum of the voltage responses from the individual devices. The signal can be added up and subtract when they are in parallel (FIGS. 13A and 13D), antiparallel (FIGS. 13B and 13C), in series (FIGS. 16A and 16D), and antiseries (FIGS. 16B and 16C). The results satisfy the ‘switching-polarity’ and ‘linear superposition’ criteria and confirm that the electric output is indeed generated by the device. Furthermore, a commercial capacitor can be charged through the AC from the device under illumination conditions (FIG. 17).

### Example 3: Mechanism

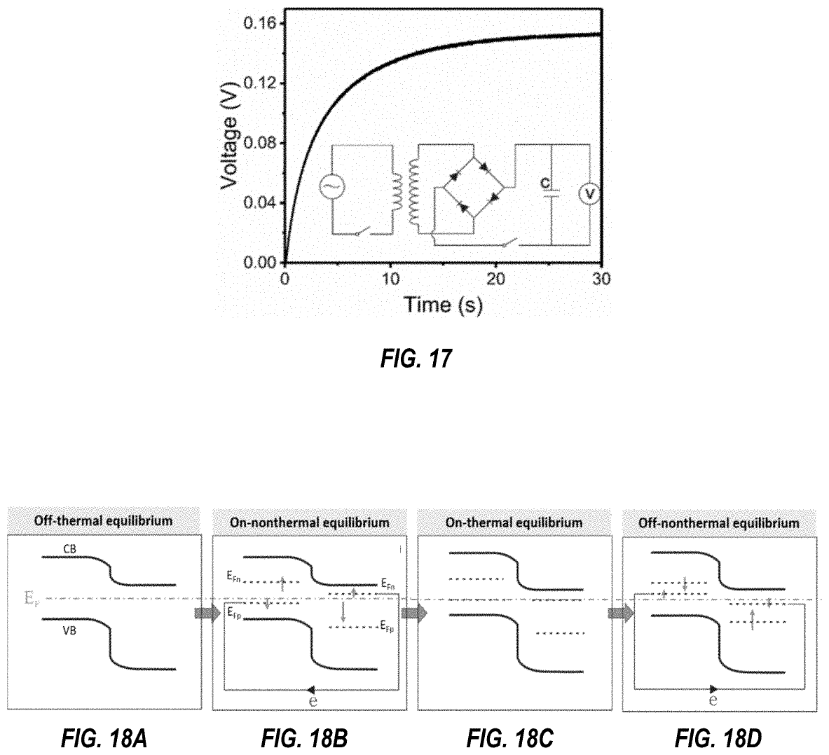

We take a pn junction device as an example. At the equilibrium status of the system in the dark, the concentrations of donor, acceptor, and recombination center are stable, and they are determined by the Fermi levels and distribution functions (FIG. 18A). The net carrier concentrations are constant and independent of time, the generation and recombination processes must be equal as follows:

$${n}_{0} {p}_{0} = {n}_{i}^{2} = {N}_{c} {N}_{v} exp ( - \frac{{E}_{g}}{kT} ) ;$$

where n₀,p₀ are thermal equilibrium electron and hole concentrations that are independent of time, nᵢ is the intrinsic carrier density, N_{c} and Nᵥ is the effective density of states in the conduction band and valence band, E_{g} is the energy gap, k₀ is the Boltzmann constant, and T is the temperature.

When the light starts to shine on the semiconductor, it perturbs the original equilibrium condition due to the light excitations and increased local temperature. In this non-equilibrium condition, excess electrons Δₙ and holes Δₚ are created in pairs (Δₙ=Δₚ), and the carriers' generation rate is larger than the recombination rate, thus np≠n₀p₀=nᵢ². The total electron concentration and the total hole concentration are functions of the quasi-Fermi levels:

$${n}_{0} + Δ n = {N}_{C} exp ( \frac{{E}_{fn} - {E}_{C}}{k T} ) = {n}_{i} exp ( \frac{{E}_{f n} - {E}_{i}}{k T} )$$

$${p}_{0} + Δ p = {N}_{V} exp ( \frac{{E}_{V} - {E}_{f p}}{k T} ) = {n}_{i} exp ( \frac{{E}_{i} - {E}_{f p}}{k T} )$$

where E_{C}, E_{V} are the energy levels at the bottom edge of the conduction band and top edge of the valence band, respectively, E_{Fp}, E_{Fn} are the quasi-Fermi energy levels for electrons and holes, respectively, Eᵢ is the intrinsic Fermi level. The two equations above directly imply that, if free electron-hole pairs are generated, E_{fn} moves upwards whereas E_{fp} moves downwards in the bandgap. For a p-type semiconductor at the low-injection condition (Δₚ<<p₀), since the majority carrier hole concentration does not change much relatively, the quasi-Fermi level for holes E_{Fp} moves slightly closer to the valence band, and it is not much different from the thermal-equilibrium Fermi level E_{F}; the minority carrier-electron concentration increase significantly (n₀ is low), the quasi-Fermi energy level for electrons E_{Fn} deviates much from E_{F} and shifts up consequently toward the conduction band side. This is similar for an n-type semiconductor (FIG. 18B).

The Acrylic plates covered before the samples to control the illumination area size. The plates were covered around by 3 layers of aluminum foil, and the center was cut by laser cutter (Universal Laser Systems, PLS9.75).

To balance the Fermi levels, electrons will flow from the high to low E_{F} side through an external load until an equilibrium is reached, because the resistance of the barrier height is high enough to block the flow of electrons in reverse. In the capacitive model, the electrons accumulate at the interfacial region between the left electrode and the semiconductor until the Fermi levels of the electrodes reach a new equilibrium value. When excess carriers are generated, the conductance of the semiconductor significantly increases and the induced potential is proportional to the amount of excess carries excited, so the current increases significantly.

After a period of illumination, the system builds up a new thermal equilibrium. The concentrations of excess electrons and holes in the system reach a steady-state, and the generation rate and recombination rate are equal and independent of time. Under this new equilibrium state, in short circuit condition, the DC current by photovoltaic effect is generated under the light, and the E_{Fp} for p type and the E_{Fn} for n type are at the same level (FIG. 18C, dotted line), and closer to the valance band in the p-type semiconductor.

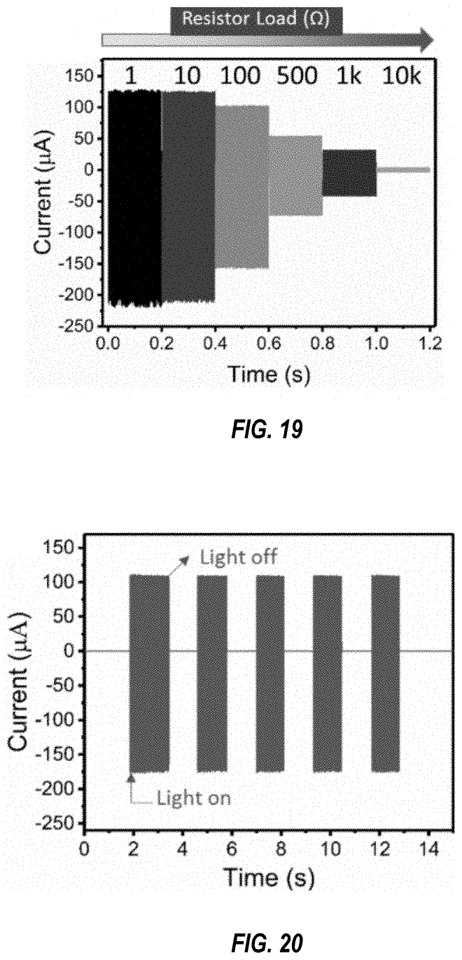

When the light is turned off, the electrons will gradually fall down to the valence band and recombine with holes; during this process, the recombination rate of charge carriers is greater than the generation rate. For the p-type semiconductor, since the majority carrier hole concentration does not change much, the quasi-Fermi level for holes E_{Fp} moves slightly away from the valence band; the minority carrier-electron concentration has decreased significantly relatively, and consequently, the quasi-Fermi energy level for electrons E_{Fn} shifts down. The n-type semiconductor behaves in a similar manner (FIG. 19). To balance the Fermi levels, the electrons that had accumulated near the left electrode flow back through the external circuit to the right electrode, returning the system to its original state. The excess electron-hole pairs disappear, and the concentrations of electrons and holes have to decrease to the original value in dark. Finally, the semiconductor returns to the initial thermal equilibrium state in dark as well as the thermal equilibrium Fermi level (FIG. 20).

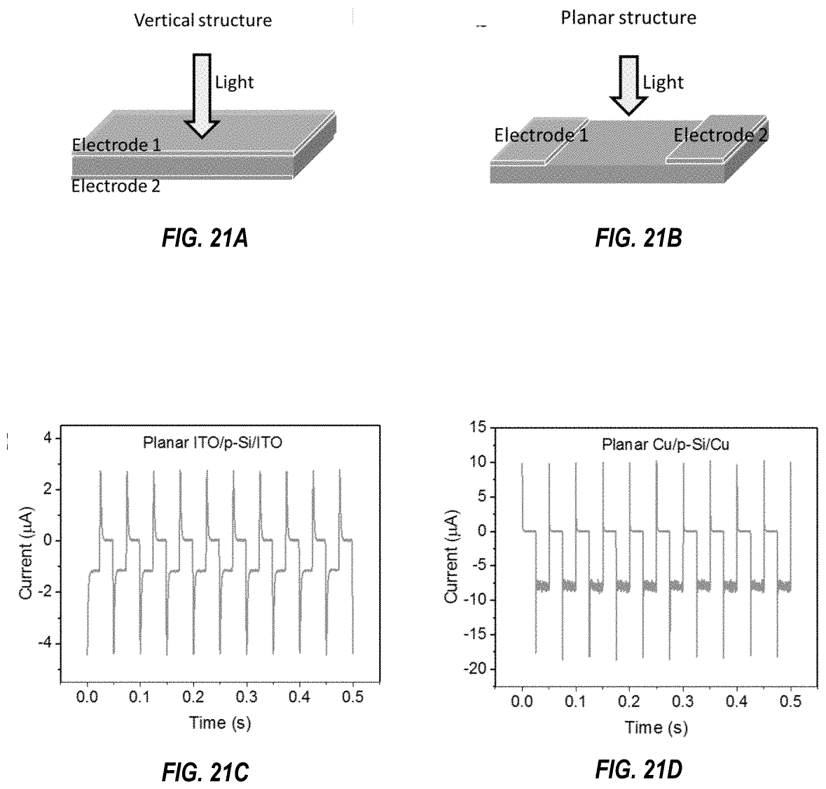

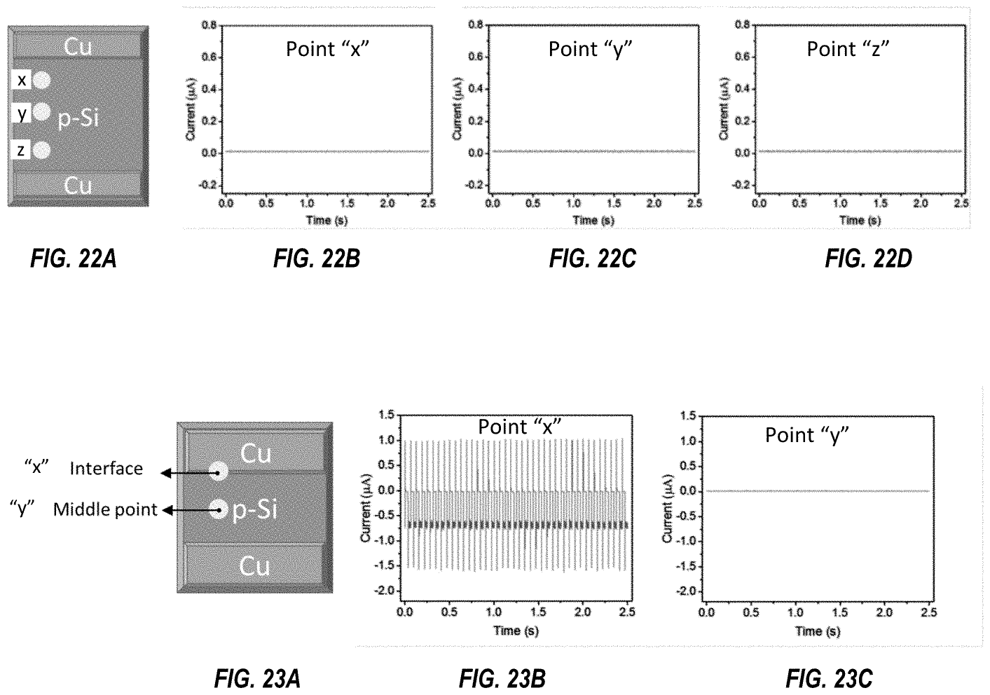

The effect is not caused by the concentration difference of excited carriers between the illuminated area and dark area (FIGS. 21A-21D and FIGS. 22A-22D). FIGS. 21C and 21D show plots of current-time (I-t) characteristic of a planar Metal-Semiconductor junction of ITO/p-Si/ITO (FIG. 21C) and a planar Metal-Semiconductor-Metal junction of Cu/p-Si/Cu (FIG. 21D), under the illumination of 442 nm at the chopper frequency of 20 Hz with zero bias. The laser beam was shone upon the whole device. These two devices with planar structure both have AC output, these results demonstrate that under the same illumination conditions, this AC output will be generated as well. Thus, this effect is not caused by the concentration difference between illuminated and non-illuminated areas (Dember effect). As shown in FIGS. 22A-22D, when the light is illuminated at the bulk material, there is no AC.

### Example 4: Measurement for Devices with Vertical Structure and Planar Structure

The results in the article are based on the vertical structure, in which two transparent electrodes are placed along the direction of light, at different sides of the semiconductors. In this case, excess carriers induced by the light only generated at one side. This would create the carrier concentration difference on two sides. To eliminate this factor and explore the mechanism, we also investigated the devices based on planar structure. In the planar structure, two electrodes are placed on the same side. So that when the light introduces, the carriers' concentration would be the same. We fabricated two devices based on planar structure, ITO/p-Si/ITO and Cu/p-Si/Cu. The two devices were under the illumination of 442 nm wavelength light at 20 Hz. The laser beam was expanded by an objective.

As shown in FIGS. 21A-21D, the vertical structure, like sandwich structure, consists of two electrodes at the different sides of the silicon wafer. The planar structure has two electrodes at the same sides of the silicon wafer. The current-time (I-t) characteristic of the devices based on the planar Metal-Semiconductor junction of ITO/p-Si/ITO and Cu/p-Si/Cu, under the illumination of 442 nm at the chopper frequency of 20 Hz with zero bias.

The laser beam was shone upon the whole device. These two devices with planar structure both have AC output, these results demonstrate that under the same illumination conditions, this AC output will be generated as well. Thus, this effect is not caused by the concentration difference between illuminated and non-illuminated areas (Dember effect).

### Example 5: Illumination at Bulk Materials and Position Changes

When the laser beam shines on the semiconductor, it may induce higher concentration of excess carriers at this point and create the concentration difference between the illuminated area and dark area. To explore the mechanism, the laser beam was focused at different points at bulk p-Si, labeled as “x”, “y”, and “z”, where “y” is the middle point of two electrodes. The frequency of flashing 442 nm light is 1000 Hz. At these three different points, there was no AC. The results reveal that the AC is not associated with the concentration difference and the diffusion of carries between the illuminated and non-illuminated faces of a semiconductor. This result demonstrates that the AC is not produced by Dember effect. The illumination at only p-Si would not generate AC.

### Example 6: Flashing Light Illuminated at the Interface and Bulk

When the flashing light is illuminated at the interface of two materials (point x), the AC current is generated. However, when it is only illuminated at the p-Si (point y), there is such AC signal. These results reveal that the AC current could only be produced when the flashing light work at the interface of two materials.

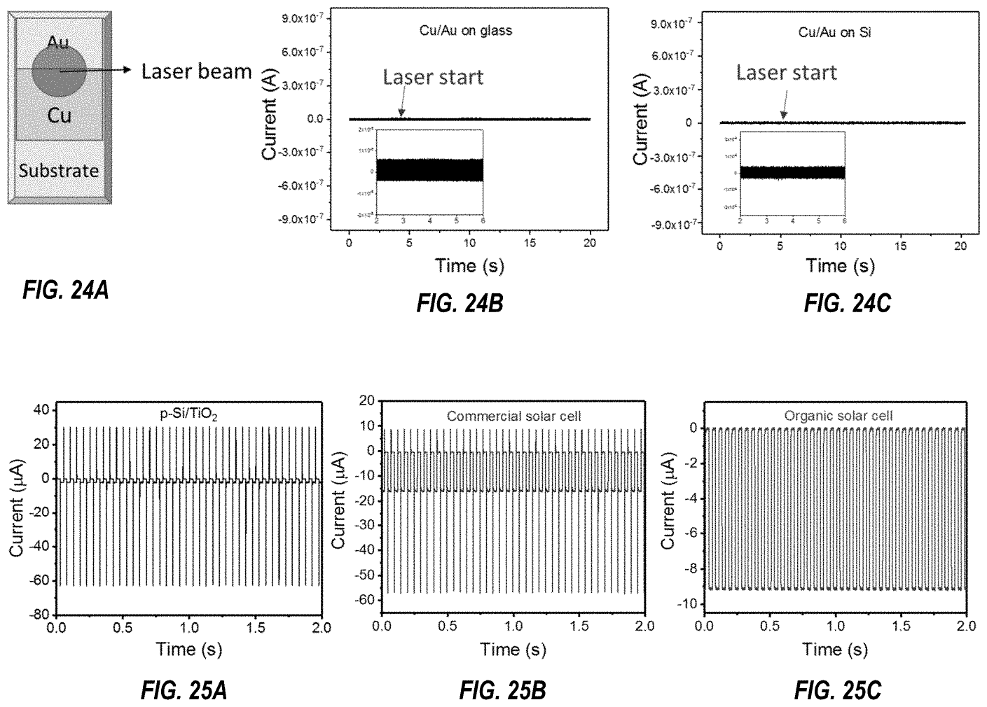

The flashing light should be illuminated at the interface of two materials to induce the relative shift of quasi-Fermi levels (FIGS. 23A-23C), and at least one of two materials is semiconductor to generate excessive carries (FIG. 24A-24C).

### Example 7: The Flashing Light Illuminated at the Interface of Metals

For metals, the Fermi level would not shift when the flashing light introduces⁵. So introduced flashing light at the interface of two metals to check the signals. Both glass and silicon are used as substrates, and 100 nm thickness of Copper and 15 nm thickness of gold nanofilm were deposited by Denton Explorer E-beam evaporator. The laser beam was expanded by an objective. We find that there are no obvious signals but noise, the noise is significant since the two materials are conductive, and the resistance is so low. These results reveal that one of the two materials needs to be a semiconductor to generate AC.

### Example 8: The Measurements of Different Devices Under the Flashing Visible Light

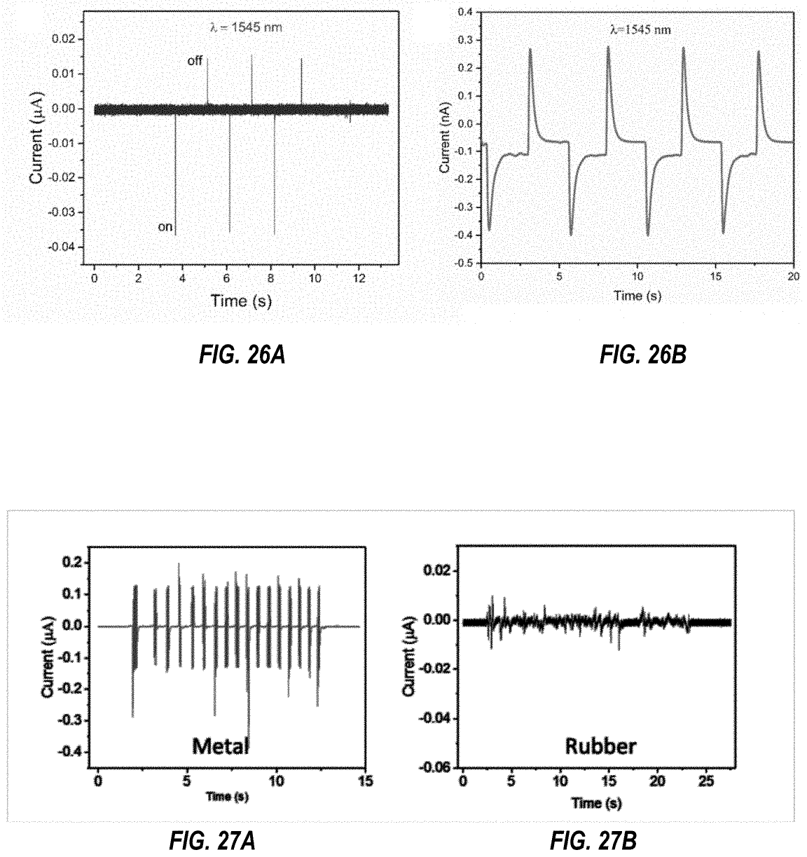

Additional experiments were conducted to verify the proposed mechanism. Commercial silicon solar panels are based on p-n junction semiconductor, the AC output was also observed under the illumination of 642 nm laser (FIG. 25A-25C). Organic photovoltaics are made of electron donor and electron acceptor materials rather than semiconductor p-n junctions, there is no shift of quasi-Fermi levels under non-equilibrium conditions. Therefore, an organic solar cell was fabricated and measured under the illumination of 642 nm laser periodically. No obvious AC was generated in organic solar cell.

To demonstrate the mechanism of this effect, different devices were measured under the visible light at 642 nm at a frequency of 20 Hz, including the fabricated device based on p-Si/TiO₂ nanofilm, a commercial solar cell (Sundance Solar Products Inc., 700-10850-28), and the fabricated organic solar cell. The measurement setup is the same as shown in FIG. 2A. The device based of p-Si/TiO₂ and commercial solar cell, which are typically p-n junction semiconductor, exhibit both AC and DC parts in the output signals. However, for organics solar cell, there is no obvious AC part. This would also demonstrate that the signals are true signals generated from the devices, rather than produced by the measurement system error or from environment noise.

The surface energy levels within the bandgap would be another effect that contributes to the mechanism. The interband absorption of light for silicon is below 1,100 nm, but when the 1545 nm light is illuminated at the junction, the effect is observed as well (FIGS. 26A and 26B). This demonstrates that the effect is not limited by the bandgap. When the system is in a state of thermal equilibrium, there are no excess carriers and no Fermi level shift, and the surface energy levels are in steady state. When the light turns on, a relative shift of quasi-Fermi levels may cause a significant amount of charges to be transferred and/or redistributed within the surface and/or the bulk. The empty surface energy levels trap the electrons and then are negatively charged, which result in a potential difference between electrodes to drive the current flow through the external circuit to balance the charges. When the light turns off, in this non-thermal equilibrium, the Fermi levels shift back, the excess carriers gradually disappear, and the neutralized energy levels lose electrons and become positively charged. This drives the current flow in the opposite direction to return to the initial state. The surface energy states have the ability to store electrons, which would clarify the capacitive model.

The excess carriers can be induced not only by light, but also by transient electric or other energy transmission methods, which can also break the equilibrium condition. Here we demonstrate that when a metal probe contacts a semiconductor, it injects excess carriers into the device, the same effect is observed as well (FIGS. 27A and 27B).

### Example 9: Applications

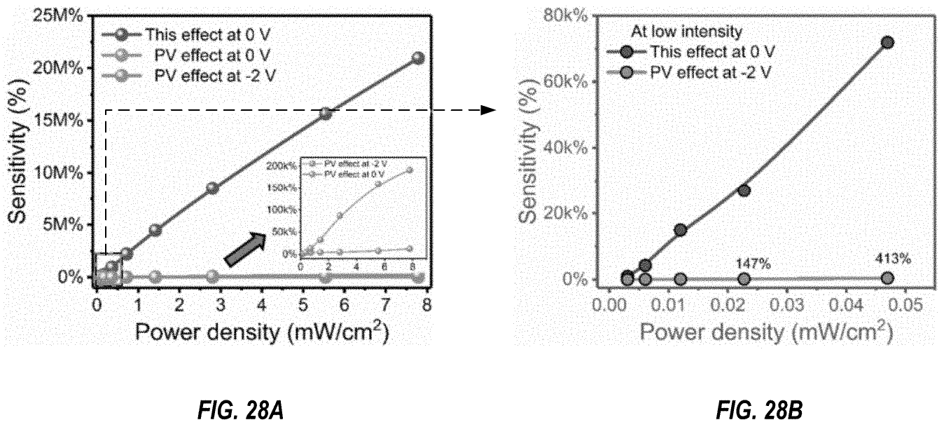

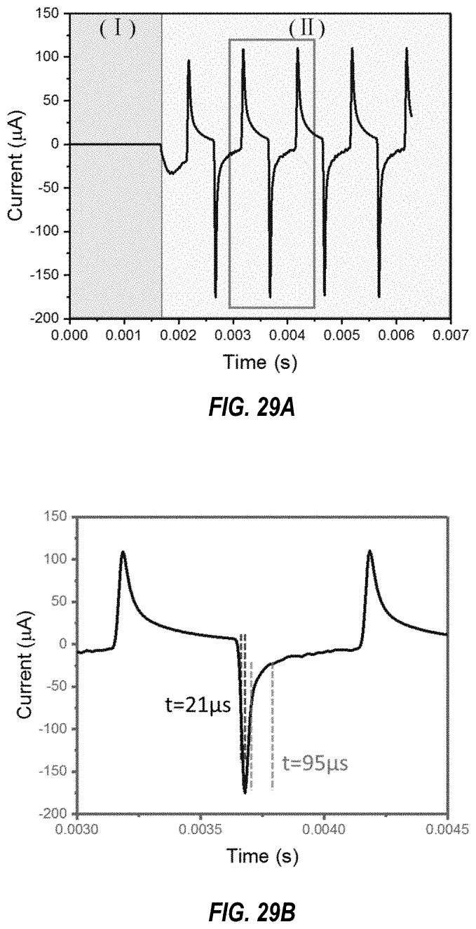

This effect can have many practical applications, such as active sensors and power sources. Broadband photodetectors have extensive applications in communication systems, medical and thermal imaging, environmental monitoring, and defense technology. For such applications, the photodetectors must satisfy stringent requirements such as high sensitivity at operating wavelengths, high response speed, and minimum noise. The principle of the traditional photodiode is the interband absorption of light in the depletion layer of the diode and the subsequent separation of electrons and holes by the electric field. An external voltage bias is always applied to strengthen the internal electric field; however, this will lead to a large dark current and require external power to drive the device. By using this effect, the fabricated device demonstrated outstanding performance as a photodetector with ultra-high sensitivity, ultra-low noise and good response speed. FIG. 20 shows a typical I-t characteristic of the photodetector based on p-Si/TiO₂ nanofilm at zero voltage under the illumination of 442 nm light with an intensity of ˜7 mW/cm² at a frequency of 1,000 Hz. The output is an AC, which is different from the output from a pn photodiode based on the conventional photoelectric effect. To measure the linearity and sensitivity, this PD was measured under various intensity. The dark current could be as low as 0.9 nA. The sensitivity defined as (I_{light}−I_{dark})/I_{dark} is found to be 2.09×10⁷% at 7.79 mW/cm² via this effect, which could be about 200 times larger than that of the same device based on the photovoltaic at −2 V bias, and more than 2,051 times larger than that via photovoltaic effect without bias (FIGS. 28A and 28B). Even at ultra-low intensities of 3, and 6 μW/cm², the sensitivities are as high as 934%, and 4,250%, while the output based on photovoltaic effect does not exhibit obvious signals at all. Higher sensitivities will enable higher signal levels and leads to more accurate results. As demonstrated, the devices have distinct advantages: operation without bias, ultra-high sensitivity even at ultra-low intensity, ultra-fast response time (as low as ˜20 μs, as shown in FIGS. 29A and 29B), and broadband response to a wide range of wavelengths from the ultra-violet to near-infrared light (FIGS. 9A-9D and 10A-10H).

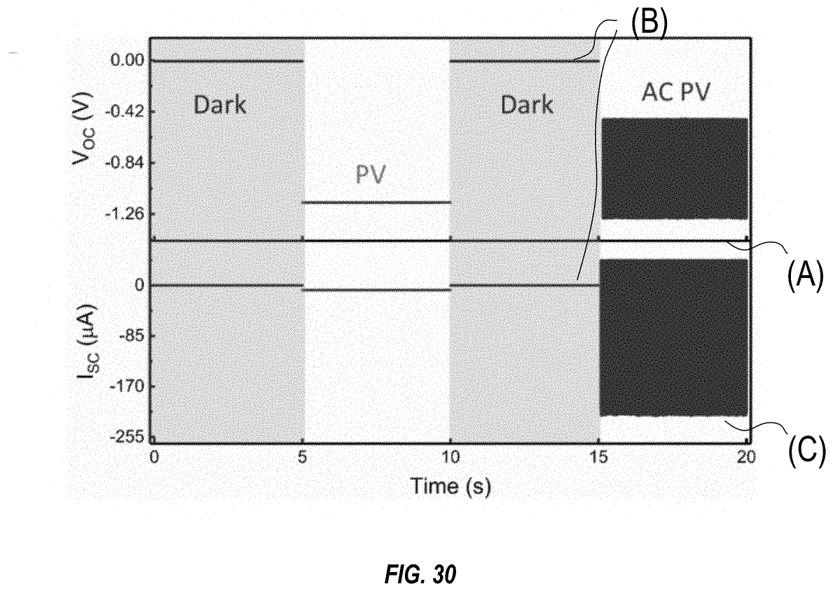

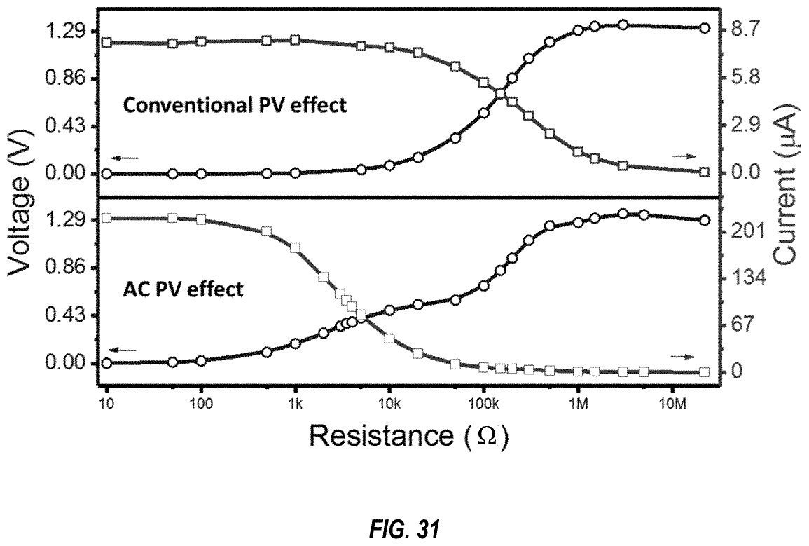

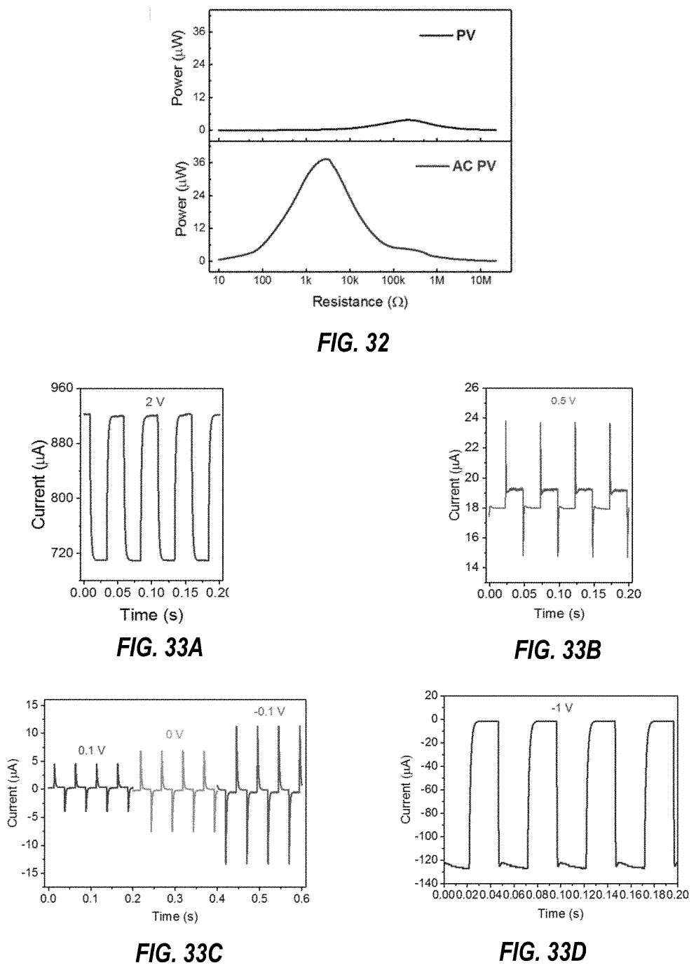

Aside from sensor applications, it can also work as a power source for small scale device. Energy densities were investigated by connecting it in series with external variable resistors under the 442 nm light illumination of 7.79 mW/cm², at a fixed chopper frequency of 1,000 Hz. Apparently, the current decreases with the increment of resistance from 1Ω to 1 MΩ, and the power densities increase sharply first, and are subsequently saturated when the load resistance is increased to 400Ω, but diminishes to nearly zero when the resistance is increased to 1 MΩ (FIGS. 19 and 28B). The maximum current density is 347 μA/cm², and the power density, the amount of power per unit volume, is as high as 103 Wh L⁻¹, which is comparable to the energy density of lead-acid and Ni—Cd batteries. A commercial capacitor could be charged by the output from the device when it was working under a periodical illumination. We connected the device to a transformer and a rectifier first, and then connected it to a capacitor with a capacitance of 0.15 μF. FIG. 17 shows that the capacitor was fully charged in about 10 seconds. The short-circuit transferred charges in the AC regions are calculated by integration, and it is around 22 nC per single peak cycle. Since the frequency can be easily modulated to a high value as compared to other direct physical contact modes, the total charges transferred could be large per unit of time, and therefore the capacitor charging process would be very fast. In addition, a mini commercial solar panel was also used to demonstrate the application of this effect in boosting the output of the photocells. The electric output of the device was studied under the illumination of 642 nm laser with an intensity of 11.10 mW cm⁻². The radius of the laser beam is about 1 cm. By the conventional PV effect, the open circuit voltage (V_{OC}) and short circuit current (I_{SC}) of the commercial solar panel were measured to be ˜1.2 V, and 8 μA, respectively. Via the alternating current photovoltaic (AC PV) effect, the same device has a maximum V_{OC} of 1.3 V, and a maximum I_{SC} of 219 μA (FIG. 30). The electric output of the device under different external loads was further studied under the same illumination conditions. The device was connected with different resistors from 10Ω to 22 MΩ. As displayed in FIG. 31, all the current amplitudes drop with increasing load resistances owing to ohmic loss, whereas the voltages follow a reverse trend. As a result, the instantaneous peak power is maximized at matched load resistances. The commercial solar panel is capable of stably delivering a maximum output power of 3.77 μW with a load of 200 k Ω, while by utilizing the AC PV effect, it could reach 4.49 μW at the same load. However, the maximum power output could reach up to 37.63μW with a load of 2 kΩ provided by AC PV effect, about 11.2 times larger than the maximum output provided by the conventional photovoltaic effect (FIG. 32). Consequently, via the AC PV effect, the output power evidently enhanced compared to that of conventional PV effect, which is a significant improvement in using the devices as a power source.

The long-term durability of the power knit has been shown in FIG. 5B, where there is no decrease at all after millions of cycles, clearly demonstrating the practical value of this stable and reliable electric power source. The non-contact mode of operation has no friction between materials, so there would be no material's wearing, leading to high durability. As the laser has a good spatial coherence, the power delivered by the laser has less energy loss in the light transfer process and could avoid the limitations and hassle of electric wires to function as a remote wireless power supply system. The output power of the system can be adjusted precisely and easily by various methods, including light intensity, switching frequency or illumination area. Overall, the utility model has great potential application in sensing for human-machine interfaces, environmental monitoring, and security. It has the advantages of a simple structure, easy fabrication and assembly, low cost and small volume size. The laser light working as a power source, it can transport energy via vacuum or harsh environments that humans cannot access, and the devices could be used as sustainable remote wireless power sources. We believe the further improvement on the output and the large-scale integration technologies would make them suitable for large devices and electrical appliances.

In summary, a new type of photovoltaic effect has been discovered that an AC electric power is generated at the transition states when the light periodically illuminated at the interface of materials. The effect is strongly affected by the light intensity, switching frequency, and illumination area and is truly universal since it exists for various types of junctions under a wide range of wavelengths. Additionally, the system operates in non-direct contact mode and has excellent long-term durability. The effect is likely due to a relative shift between the quasi-Fermi levels of the semiconductors adjacent to the junction/interface under the non-equilibrium conditions, which results in an electron flow in the external circuit to balance the potential difference between the electrodes. It could have significantly higher current output than that from DC output via photovoltaic effect. Using the new effect, the device that could work as an active photodetector that has a significant higher current than that produced by conventional PV effect, and ultra-low dark current without a voltage bias, resulting in an ultra-high sensitivity even at ultra-low light intensity. Additionally, with the new effect, it could boost the power output from photocells. Our study opens a valuable route for improving the performance of optoelectronic devices.

### Example 10: Methods

Fabrication Process of the devices: P-type Si wafers (B-doped (100) wafer, 1-10Ω cm, UniversityWafer Inc.) were washed by ultrasonicator with acetone, isopropyl alcohol, and distilled water respectably for 20 minutes. The wafers were cut into pieces by dicing saw, each piece had a size of 1 cm×1 cm. The devices with different junctions were processed via E-beam evaporator, physical vapor deposition (PVD) radio frequency (RF) sputter, and atomic layer deposition (ALD). TiO₂, AlOₓ with a thickness of 15 nm was coated by Cambridge NanoTech Plasma ALD. ITO was deposited by PVD75 RF Sputterer, Kurt J. Lesker Company. The thickness of the ITO layer was about 100 nm. Cr and Al were deposited by Denton Explorer E-beam evaporator with a thickness of 200 nm.

Commercial solar panel: The mini solar panel was purchased from Sundance Solar Inc. Item model number is 700-10850-28.

Fabrication of ZnO nanowires: ZnO seed layer was deposited by RF magnetron sputtering (PVD RF75, Kurt.J. Lesker Company) with a thickness of about 100 nm. The coated samples were then placed into mixed growth solution (25 mM Zn(NO₃)₂, 12.5 mM hexamethylenetetramine, and 0.8 M ammonium hydroxide) in a mechanical convection oven (Yamato DKN400, Santa Clara, Calif., USA) at 95° C. for 90 minutes. The samples were washed with isopropyl alcohol and distilled water and dried in the oven at 60° C. for several hours. Poly(methyl methacrylate) (MicroChem 495PMMA A8) was span coated onto the samples, and then the samples were treated with oxygen plasma by reactive ion etching (Vision RIE) for 4 minutes to expose the tips of ZnO nanowires. A thin layer of ITO was deposited on ZnO as the top electrode and Al was deposited on p-Si as the bottom electrode. Samples then were cleaned with acetone to remove the PMMA layer and fired at 350° C. for 2 hours in a compact rapid thermal processing tube furnace (RTP-1000D4, MTI Corporation). Testing wires were connected to the electrodes by silver paste.

Measurements: I-V characteristics of the devices were measured and recorded by a computer-controlled measurement system with a Stanford SRS low noise current preamplifier (SR570)/SRS low noise voltage preamplifier (SR560) in conjunction with a GPIB controller (GPIB-USB-HS, NI 488.2). I-t characteristics of the devices were measured by the current preamplifier (SR570) without filter. V-t characteristics of the p-Si/TiO₂ device was measured by the low noise voltage preamplifier (SR560) and Keithley 6514 electrometer. The sample rate is 10⁵ samples per second. The optical input stimuli were provided by a He—Cd laser (wavelength=442 nm, model no. KI5751I-G, Kimmon Koha Co., Ltd.). A continuously variable filter was used to control the light power density, which was measured by a thermopile power meter (Newport 818P-001-12).

### Example 11: Capacitive Model

In a resistive conduction model, due to inelastic collisions with atoms and electrons, the related resistance limits the free electrons flow, producing a steady state current. The I-V curve of the device follows the Ohm's law for the resistive conduction model.

The foundation of the capacitive model is the displacement current. The displacement current was first postulated by Maxwell. Different from resistive conduction model, the displacement current is not an electric current of moving charges, but a time-varying electric field, and a contribution from the slight motion of charges bound in atoms. Carrier transport is affected by an electric field and by a number of physical phenomenon-such as carrier drift and diffusion, trapping, injection, contact-related effect, impact ionization, etc.

Based on a capacitive model, the output current can be represented by

$$I = \frac{d Q}{dt} = C \frac{d V}{dt} + V \frac{d C}{dt}$$

where Q is the charges transferred, t is the time of the charges transfer process, the first term is the current introduced by a change in the applied voltage; the second term is the current introduced by the variation in capacitance. In this case, the change in capacitance is rather small because there is little change in crystal size nor thickness, so that the current is mainly due to the change in the potential with time. When the light is on, the Fermi levels shift and the excess carriers start to accumulate, and the imbalance of energy states drive the charges to flow, and the driving force is large at the beginning; as more charges flow to balance the Fermi levels, the difference of Fermi levels reduces so as the potential difference. So the current increases significantly and then drops after the peak.

### Example 12: The Relationship Among Frequency, Time and Current

The charges transferred between the two electrodes are driven by an induced potential. The induced potential is proportional to the number of excess carriers excited². When the frequency changes, the total amount of charges transferred does not change much under the same illumination condition, as well as the potential (FIG. 2B).

The optical chopper is used to interrupt a laser beam periodically. The switching time is inverse of chopper frequency. The time interval from fully bright to fully dark (we define it as specific on-off time) is determined by the rotating speed, disc radius, beam position and beam diameter. The specific on-off time is estimated by calculation, shown in FIG. 4B. Then, we define the specific rise time is the time interval from the point when the laser is on to the peak point; the specific fall time is the time interval from the point when the laser is off to the other peak. The total rise time is defined as the time interval from the point when the current starts to grow to the first point of photocurrent. Similarly, the total fall time is defined as the time interval from the point when the current starts to decrease to the first point of dark current. This demonstrates that the output signal is strongly correlated with the illumination of the laser. The current is defined as a flow of electrical charge carriers per unit time, thus the cycle time reduces as the chopper frequency increases, while the charges remain the same under the same condition, the current would increase accordingly.

### Example 13: Linear Superposition Rule Verification

Artifacts or noise may occur in the measurements due to various sources, such as a change in the system capacitance, leakage of electric current from instruments, movements of wires, and even airflow in the environment.

To identify true signals rather than artifacts or noise, we employed 2 devices, and used the linear superposition rule of current and voltage in all 8 configurations to rule out artifacts.

Two devices, named Dev 1 and Dev 2, were used, in which the Dev 1 had higher output. We define I₁⁺, and I₂⁺ for positive connection of Dev 1, and Dev 2 according to FIG. 12 and FIGS. 13A-13D. We define I₁⁻ and I₂⁻ as negative connection when the device is reversely connected. When the devices are connected in series or in parallel, the total current measured by current meter is labeled as the combination of two, such as I₁⁺I₂⁺.

When Dev 1 and 2 are connected in parallel, the measured current should obey:

I₁⁺I₂⁺=I₁⁺+I₂⁺ (1)

I₁⁻I₂⁺=I₁⁻+I₂⁺ (2)

I₁⁺I₂⁻=I₁⁺+I₂⁻ (3)

I₁⁻I₂⁻=I₁⁻+I₂⁻ (4)

It is worth to note that I₁⁺I₂⁺=−(I₁⁻I₂⁻); I₁⁻I₂⁺=−(I₁⁺I₂⁻). This testing result also rules out the artifacts from the environment or the instruments. For the artifacts not from the devices, they won't reverse their polarity even we switch the connection mode reversely. Similarly, we define in the same way for V₁⁺, V₂⁺, V₁⁻, V₂⁻, and the total voltage measured by voltage meter, such as V₁⁺V₂⁺. When Dev 1 and 2 are connected in series, the measured voltage should obey:

V₁⁺V₂⁺=V₁⁺+V₂⁺ (1)

V₁⁻V₂⁺=V₁⁻+V₂⁺ (2)

V₁⁺V₂⁻=V₁⁺+V₂⁻ (3)

V₁⁻V₂⁻=V₁⁻+V₂⁻ (4)

It is also worth to note that V₁⁺V₂⁺=−(V₁⁻V₂⁻), V₁⁻V₂⁺=−(V₁⁺V₂⁻).

### Example 14: Under the Flashing Light of 1545 nm Light

Considering the boundary conditions at a semiconductor surface, the disruption of the periodic-potential function results in allowed electronic energy states within the energy bandgap. The allowed energy states within the energy bandgap are also approved by experiments: when the p-Si/TiO₂ system was under the illumination of 1545 nm light, the signal had photocurrent produced by the photovoltaic effect, and the carriers can be excited by the 1545 nm near-infrared light. The interband absorption of light is below 1100 nm, FIGS. 33A-33D show that the p-Si are able to absorb certain amount of 1545 nm light because of allowed electronic energy states within the energy bandgap. AC output was also produced by 1545 nm light.

### Example 15: Impact of Bias Voltage on the Output

Impacts of bias voltages on the performance are carefully studied by comparing the results of the device p-Si/TiO₂ nanofilm operating under different bias voltages when a power density of 7.79 mW/cm² illumination at the chopper frequency of 20 Hz, as shown in FIGS. 33A-33D. I-t characteristics biased at voltages ranging from −1 to 2 V are presented. At relatively high positive (+2 V, FIG. 33A) or low negative voltages (−1 V, FIG. 33D), only DC is produced via the conventional photovoltaic effect. The obvious four-stage responses can be seen from the results with an applied voltage of 0.5 V, but there is no negative current, this is because the current is the algebraic sum of currents generated from the two effects, the dark current is high. As the voltage sweep from +0.1 to −0.1 V, the AC increases, as well as the DC part. These results indicate that an appropriate external reverse voltage would maximize the AC, however, too high voltages would eliminate the AC. These can be explained by the surface effects discussed below.

### Example 16: Surface Effects

Considering the boundary conditions at a semiconductor surface, the disruption of the periodic-potential function results in allowed electronic energy states within the energy bandgap. For p-type silicon, minority carriers-electrons could be captured by the empty energy states, if exist, within the forbidden bandgap. The empty energy levels, are initially neutral in the thermal equilibrium state, and then are filled up with excess electrons; that is, they will be negatively charged when they capture electrons and result in the potential difference between two electrodes and current flow in the system when it is in short circuit connection.

High E_{F} side of the surface energy levels lose electrons (FIG. 18D) and so positively charged, and electrons flow backward respectively. It is notable that the trapping would also cause the corresponding additional conductivity.

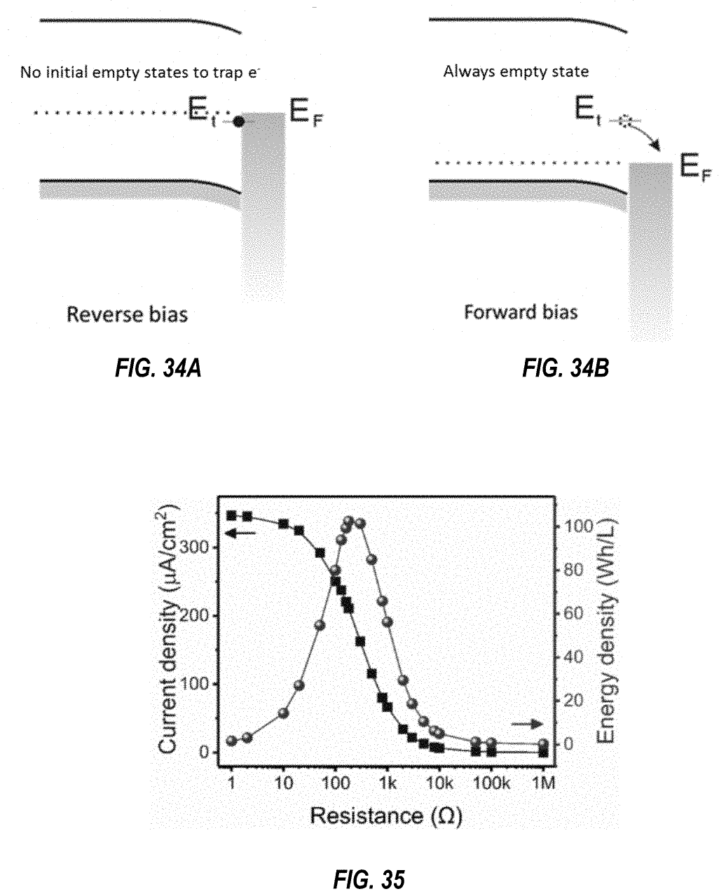

However, whether certain defect energy levels can capture electrons depends on the energy level positions and states. To capture electrons, the energy levels should fulfill several requirements. First, the allowed energy states should be empty to be allowed to capture electrons. The energy levels should be close to the Fermi level in the thermal-equilibrium. For lower energy levels, the energy states are already filled with electrons, could not trap more; for energy levels above the Fermi level, the energy levels are empty, which are suitable for capture electrons, however, if it is too high, electrons are easy to escape since the energy levels are closer to conduction band. Similarly, the externally applied voltages would shift the Fermi levels. FIGS. 34A and 34B show a schematic of the status of allowed energy levels on the surface under reverse bias (FIG. 34A), or forward bias (FIG. 34B). In the case of reverse bias, the surface states are not empty, electrons are not able to be trapped. In forward bias, the surface states are too high, electrons are not able to reach the energy levels, so they are always empty. If a high absolute value of reverse bias is applied, the energy levels Eₜ is already filled with electrons (FIG. 34A), they are not able to capture more electrons. When a high value of forward bias is applied, then these energy levels would be high due to the external bias. Due to the light-induced excess carriers, the Fermi levels will shift, but the Fermi levels would be still lower than these high energy levels, then the energy levels Eₜ will not be filled with electrons (FIG. 34B). So, the external voltages should not be high, otherwise, this AC would not be produced. Second, the energy levels with obvious trapping effect must have two greatly different electron capture coefficient rₙ and hole capture coefficient rₚ, to trap the non-equilibrium minority carriers. For p-type silicon, rₙ>>rₚ, the system could effectively trap the non-equilibrium carriers-electrons.

### Example 17: The Excess Carriers Induced Electrically by the Contact Between the Device and Metal or Rubber

The excess carriers are able to be induced not only by photons, but also electrically. Here an aluminum stick is used to touch the device, and the other end was connected with ground. We find AC was generated when the excess carriers induced by the metal probe. Rubber was also used to induce excess carriers at the surface. Similarly, AC was generated when the rubber contact the surface of the device.

### Example 18: Photodetector Based on AC Generator

The rise time of photodetector based on AC is about 20 μs, and the fall time is about 95 μs. A comparison of photosensing properties for various photodiodes is shown in Table 1.

TABLE 1

| | | Light of | | | | | | | | |
|---|---|---|---|---|---|---|---|---|---|---|
| Material and | Device | detection | Bias | Dark | | | | Rise time/ | | |
| structure | type | (nm) | (V) | current | | Current | | Fall time | | Sensitivity |
| p-Si/TiO₂ | p-n | 325-1060 | 0 | 0.85 | nA | 178 | μA | 21 μs/95 μs | | 21M % |
| nanofilm | junction | | | | | (442 | nm) | | | |
| p-Si/ZnO NW | p-n | 442-1060 | −2 | 3.17 | μA | 131 | μA | 0.97 | ms | 4k % |
| arrays | junction | | | | | (442 | nm) | (442 | nm) | |
| ZnO NWs/Au | Schottky | 365 | 5 | 0.2 | pA | 0.1 | nA | 0.28 | s | 500k % |
| ZnO NWs/Au | Schottky | 365 | 1 | 0.03 | pA | 15 | pA | 1 | s | 500k % |
| ZnO hollow- | M-S | 350 | 5 | 50 | nA | 2.6 | μA | <5 | ms | 5.1k % |
| sphere nanofilm | | | | | | | | | | |
| ZnO NWs/i- | n-i-n | 365 | −5 | ~6.4 | nA | ~8.6 | μA | <160 | ms/ | 134k % |
| MgO/n-Si | | | | | | | | <350 | ms | |
| Monolayer | Schottky | 561 | −1 | 0.1 | μA | 1.5 | μA | 4 s/9 s | | 1.5k % |
| MoS₂/Au | | | | | | | | | | |
| MoS₂/Au | Schottky | 442 | −2 | 90 | nA | 220 | nA | 122% | | 122% |
| pSi/TiO₂ | p-n | 405 | 7 | 113 | μA | 460 | μA | 14 ms/14.6 ms | | 308% |
| SQ NWs/c-Si | p-n | 365-808 | −3 | 0.1 | nA | 7 | nA | 4-16 | s | 6.9k % |
| | | | | | | (365 | nm) | | | |
| GaTe flakes | Schottky | 532 | 5 | 10 | nA | 120 | nA | ~20 | ms | 1.1k % |

| | | | | | | | | | |
|---|---|---|---|---|---|---|---|---|---|
| SiGe QDs | p-n | 500-800,1300 | −0.5 | 20 | nA/cm² | 60 | uA/cm² | — | 220K % |
| Cr/MoSe₂/Si | p-n | 365-1310 | −2 | 1.2 | μA | 168 | μA | <0.1/<0.2 ms | 14k % |
| CuO/Si NWs | p-n | 405-1064 | 0 | 0.7 | nA | 4.6 | μA | 60μ/80 μs | 657k % |

Here, an ultra-high sensitive photodetector based on the alternating current (AC) photo-response, that uses the AC photocurrent generated by periodically modulating the incoming light in square waveform was studied. The electrons oscillate back and forth between the two electrodes at zero bias to produce large alternating photocurrents when the photon-induced excess carriers are immediately generated or quenched. The AC photocurrent offers a good combination of strong photocurrent and an extremely low dark current (˜0.18 pA), and manifests as extremely high sensitivity, detectivity, and external quantum efficiency (a maximum efficiency of 86%), which can well resolve the issues of the current photodetectors. A record sensitivity has been achieved 1.14×10¹¹%, which is more than 4 orders of magnitude higher than any previously reported high-performance photodetectors based on the conventional photovoltaic effect, and equivalent to 3,056% per photon. Even at an ultra-low intensity of 1.3 μW cm⁻², it has a sensitivity of 3.14×10⁷%. Its detectivity reaches 6.15×10¹⁵ Jones at the intensity of only 0.866 mW cm⁻², which is among the highest reported values of various devices. In addition, the response time is as fast as 7 μs, which fulfill requirements for operating at high-speed response conditions for various applications, such as nanorobotics, imaging, medical, analytical fields, and optical-fiber communication systems.

The conventional photovoltaic effect usually gives a DC output under constant light illumination. Alternating photocurrent can be produced by semiconductor devices under a periodic blinking light, as described above and shown in FIG. 1A. A photodiode based on a p-n junction was fabricated at the interface between p-type silicon and a 15 nm thin layer of TiO₂ deposited via atomic layer deposition (ALD) as shown in FIG. 1B.

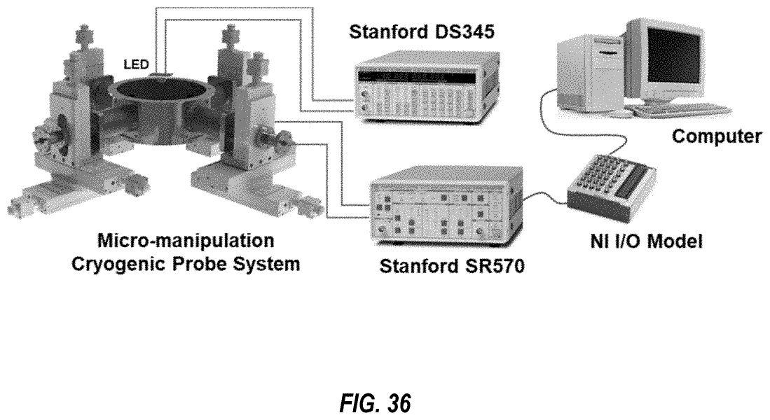

The photodetector was illuminated by a light-emitting diode (LED) with an optical excitation wavelength of 623 nm. Here, a function generator provides a voltage source with three different waveforms (sinusoidal, square, and triangular) to power the LED, and modulates the frequency of voltage input (FIG. 36). Different from pristine routine by the conventional photovoltaic effect, the photodetector is operated at zero bias under modulated light with an appropriate filter setting and high sampling rate (above 10⁵ times per second) to avoid any distortion of the acquired real signals. The comparisons with other techniques are summarized in Table 2.

TABLE 2

| | | Conventional | The devices based |
|---|---|---|---|
| | Solar cells | PDs | on AC PV |
| Materials | Organic, | Organic, | Should have |
| | inorganic, etc. | inorganic, etc. | initial carrier |
| | | | concentrations |
| | | | (n₀, p₀) |
| External voltage | No | Yes | No |
| Light | Stable | Switch | Switch/flashing |
| Relation with switch | — | No | Yes |
| frequency | | | |
| Output (AC/DC) | DC | DC | AC |

The requirements for measuring the alternating current of optoelectronics include (a) at least one of the materials should have initial carrier concentrations as p-type or n-type semiconductors; (b) the light should illuminate at the junction of the materials; (c) the devices are operated at zero bias or relatively small voltage (usually <0.2 V). No AC is generated if a relatively high voltage is applied (eg. 0.5 V, 1 V); (d) the devices are under non-thermal equilibrium conditions, that the generation and quenching of electrons and holes switch fast to induce the electrons to flow forward and backward; (e) an appropriate filter setting is required for recording the real signals and the signals have a very short decay time, and the spines are usually be treated as noises by systems if the inappropriate filter setting is applied, they will be filtered out; (f) a high sampling rate (>10⁵-10⁶ Hz) is needed to record the full shape of the signals; and (g) big memory size for the measuring computer is needed for recording the big data.

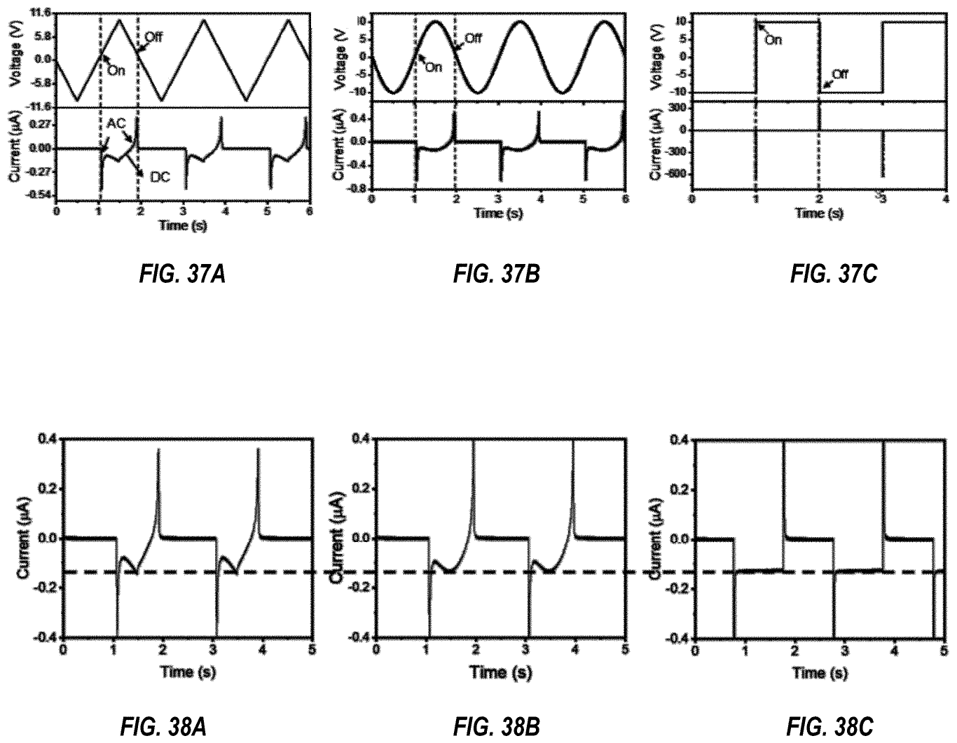

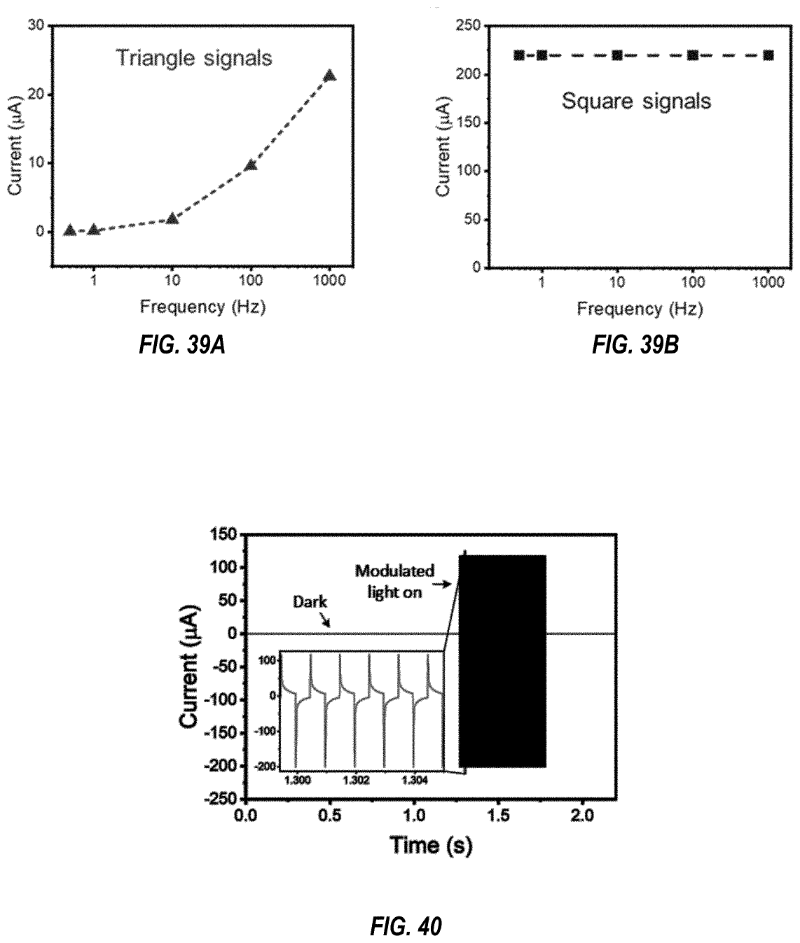

From FIG. 37A-37C, the current output is made of two components: direct current (DC) and AC. The AC component occurs only at the transition times when the light is switched on or off, while the DC component happens when the light keeps illuminating without blinking. Obviously, the DC parts are caused by the conventional photovoltaic effect and they have the same peak values that rely on the intensity of light, independent of the waveforms of the voltage input signals (FIGS. 38A-38C). When voltage sweeps, the light is turned on and off, the photodetector generates negative or positive spikes respectively under three waveforms of voltage inputs (triangular, sinusoidal, square), as shown in FIGS. 37A-37C. Under the square waveform, the device generates an ultra-high AC of up to 628 μA, significantly higher than the DC peaks of 0.14 μA. The appearance of sharp AC photocurrent is novel and cannot explained by the ordinary photovoltaic effect, especially for centrosymmetric materials, such as TiO₂. The sharp AC photocurrents are strongly dependent on the transition time of switching, which demonstrates that it is more likely to fit the charge transfer physical model. When the transferred charges are the same, a shorter transit time would lead to a higher current (FIGS. 39A and 39B), according to the definition of electric current, the flow rate of electric charge l=Δq/Δt. Therefore, it can have a significantly high current density in a semiconductor material with only a modest amount of transferred charges.

### Example 19: Generating a Significant Current Density in a Semiconductor Material with Only a Modest Charge Density Gradient

Electrons from a region of high concentration have to diffuse to a region of low concentration, thus produces a flux of electrons flowing in the negative x-direction, and the conventional current direction is in the opposite direction. The electron diffusion current density for this one-dimensional case can be written in the form:

$${J}_{nx} = e {D}_{n} \frac{d n}{d x}$$

where Dₙ is called the electron diffusion coefficient, has units of cm²/sec, and is a positive quantity.

Assuming that, in a p-type silicon semiconductor at T=300° K, the electron concentration difference is about 1×10¹³ cm⁻³ over a distance of 0.01 cm. The typical diffusion coefficient values Dₙ at T=300 K is 35 cm²/sec. Thus the diffusion current density is given by:

$$\\ {J}_{nx} \approx e {D}_{n} \frac{Δ n}{dx} = 1.6 \times 1 {0}^{- 19} \times 35 \times ( 1 {0}^{13} ) \text{/} 0.01 = 5.6 mA {cm}^{- 2} .$$

The total current density is the sum of these four components, electron drift, and diffusion currents, and hole drift and diffusion currents, in the one-dimensional case,

$$J = en {μ}_{n} {E}_{x} + e p {μ}_{p} {E}_{x} + e {D}_{n} \frac{dn}{d x} - e {D}_{p} \frac{d p}{d x}$$

Significant drift current densities can be obtained in a semiconductor under a relatively small electric field, and the majority carrier will be primarily accounted for drift current.

Inspired by the above results, ultra-high sensitive photodetectors based on alternating photocurrent are presented. The light source was modulated at a certain frequency and powered by a function generator or adjusted by a high-speed optical chopper/shutter, and photodetectors were operated at zero bias. FIG. 40 shows a typical I-t characteristic of the photodetector illuminated under a red LED powered by a square waveform at a frequency of 1000 Hz. Strong ACs (up to ˜201 μA) are generated, which is more than 12885 times higher than the DC measured at zero bias (−15.6 nA) by the conventional photovoltaic effect (stable light). The response time is as fast as 7-8 μs, which is suitable for many practical fast response applications.

Achieving sensitive detection requires not only high photo-response, but also low noise and background. When the input power of the LED is off, the dark current as low as 0.18 pA, since there is no external voltage applied on the photodetector. The dark current and noise may mainly come from the thermal random generation of electron-hole pairs, and AC from the current measurement instrument. Noise-equivalent power (NEP) is another figure of merit, which is defined as the minimum impinging optical power that a detector can distinguish from noise. A smaller NEP corresponds to a more sensitive detector. When the detector is shot-noise limited by its dark current, the calculated total noise equivalent power (NEP) can reach 1.30×10⁻¹⁶ W Hz^{-1/2}, which can be about 4 orders of magnitude lower than the data reported for most perovskite photodetectors and silicon photodiodes. The extremely low noise current at zero bias is account for achieving such a small NEP value.

### Example 20: Dark Current and Specific Detectivity

When the detector is shot-noise limited by its dark current, the shot noise from the dark current is:

$$\overline{{i}_{n , sh}^{2}} = 2 eB \overline{ {i}_{d}} = 5.76 \times 1 {0}^{- 32} B {A}^{2} {Hz}^{- 1}$$

The total noise equivalent power (NEP) for a bandwidth of B Hz is:

$$\frac{{( NEP )}_{sh}}{{B}^{1 \text{/} 2}} = \frac{{\overline{{i}_{n , sh}^{2}}}^{1 / 2}}{{B}^{1 \text{/} 2}} ℛ = 1.30 \times {10}^{- 16} W {Hz}^{- 1}$$

The specific detectivity (D*) is defined as:

$${D}^{*} = \frac{R \sqrt{A * B}}{N E P} = \sqrt{A} \text{/} \frac{N E P}{( {B}^{1 / 2} R )} = 6.15 \times 1 {0}^{15} Jones$$

if the detector is shot-noise limited by its dark current, where A is the effective area of the detector in cm², B the electrical bandwidth in Hz, and R the responsivity in A W⁻¹.

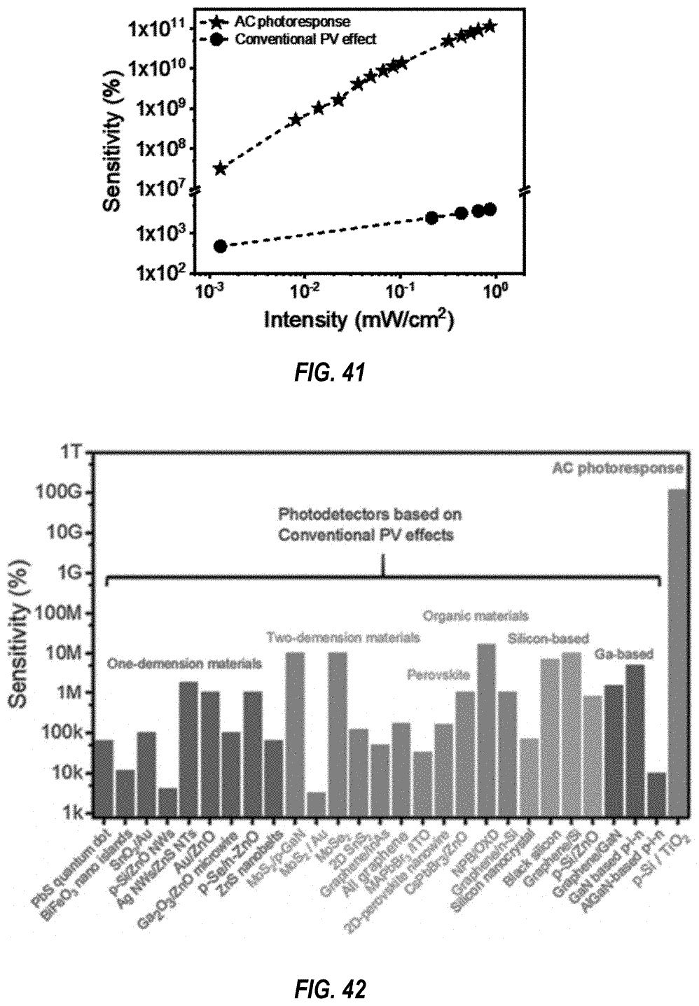

FIG. 41 shows the sensitivity of the photodetector under various intensities. The sensitivity is defined as the ratio of photocurrent to dark current (I_{light}−I_{dark})/I_{dark}. For the sensitivity of photodetector based on alternating current photoresponse, it is measured to be 1.14×10¹¹% at the intensity of 0.887 mW cm⁻², which is 2.88×10⁷ times higher than the sensitivity of 3,965% measured by the conventional PV effect (stable light, at a reverse bias of 1 V). By converting into quantum flux, the sensitivity can reach 2630% per photon.

### Example 21: Calculation of Photon Flux

The quantum flux is defined as the number of photons per second and unit area on a surface, in units of m⁻² s⁻¹. Irradiance can be converted into quantum flux (or photon flux).

A photon has a distinct energy Eₚ, which is defined by:

$${E}_{p} = \frac{h c}{λ}$$

with Planck constant h=6.63×10⁻³⁴ [J^{-S}]; speed of light c=2.998×10⁸ [m/s]; frequency f [s⁻¹]; wavelength λ [m]

The number of photons per second and surface unit, Nₚ, can be calculated from the irradiance (I) by:

$$Φ = \frac{I}{{E}_{p}} = \frac{I [ {W m}^{- 2} ] \times λ [ nm s ]}{1.988 \times 1 {0}^{- 25}}$$

as 1=0.866 mW cm⁻², λ=632 nm, ΦP=2.719×10¹⁹ m⁻² s⁻¹

As the device area is 0.64 cm²; assume the time interval from on to off is estimated to be 0.1 μs (the maximum frequency for the function generator is 10 MHz, and we take it as the maximum cycle time), and the transition time is estimated to be 0.05 μs (as there are two transition times: from on to off, and from off to on); if we suppose the light intensity is gradually increased/reduced at a fixed rate, thus, the conversion of irradiance into the number of photons at the transition time is:

$${N}_{p} = ( \frac{1}{2} ) ( Φ \times t \times S ) = 4.35 \times {10}^{7} ,$$

the measured sensitivity over a photon is about 2630.32%.

The figures of merit are characterized and compared with other high-performance devices reported in the literature as shown in FIG. 42, Table 3, and Table 4. The measured sensitivity represents an about 4-8 orders of magnitude improvement comparing with the values reported in the literature previously. Besides, from FIG. 41, the photodetector based on the alternating current photovoltaic effect has a great linearity.

TABLE 3

| | | Photo to dark | | |
|---|---|---|---|---|
| | Devices | current ratio (%) | Dark current | Response time |
| 1-D materials | p-Si/TiO₂ | 1.14E+11 | 0.18 pA | 7 ms |
| | PbS quantum dot | 6.30E+04 | 216 nA | — |
| | BiFeO₃ nano islands | 1.15E+04 | 0.69 nA | 6.97 ms; 1.2 ms |
| | SnO₂/Au | 1.00E+05 | 38 pA | 0.1 s |
| | p-Si/ZnO NWs | 4.10E+03 | 3.17 mA | 0.97 ms; 1.3 ms |
| | Ag NWs/ZnS NTs | 1.92E+06 | 0.2 nA | 0.09 s; 0.07 s |
| | Au/ZnO | 1.00E+06 | 2 pA | 0.1 s-1 s |
| | Ga₂O₃/ZnO microwire | 1.00E+05 | — | 100/900 ms |
| | p-Se/n-ZnO | 1.00E+06 | 1 pA | 0.69 ms; 13.5 ms |
| | ZnS nanobelts | 6.43E+04 | 643 pA | <0.3; <0.3 |
| 2-D materials | MoS₂/p-GaN | 1.00E+07 | 5.00 pA | 46 ms; 114 ms |
| | MoS₂/Au | <3200 | 2 pA | 4 s; 9 s |
| | MoSe₂ | 1.00E+07 | 10 nA | 100 ms |
| | | | | rise 65 ms; |
| | 2D SnS₂ | 1.20E+05 | 0.01 mA | fall 30 ms |
| | graphene/InAs | 5.00E+04 | 0.1 nA | |
| | all graphene | <170000 | 10 nA | 40 ms |
| Perovskite | MAPbBr₃/ITO | 3.25E+04 | 0.2 mA | 0.05 ms |
| | 2D-perovskite | 1.60E+05 | 0.8 pA | 27.6 ms; 24.5 ms |
| | nanowire | | | |
| | CsPbBr₃/ZnO | 1.00E+06 | 0.45 nA | 210 ms; 240 ms |
| Organic | NPB/OXD | 1.70E+07 | — | 888 ns |
| photodetector | | | | |
| Si-based | Graphene/n-Si | 1.00E+06 | 0.1 nA | 0.32 ms; 0.75 ms |
| | Silicon nanocrystal | 7.00E+04 | 2.4 nA | — |
| | Black silicon | 7.23E+06 | 4.15 nA | — |
| | Graphene/Si | 1.00E+07 | — | 4/12 ns |
| | p-Si/ZnO | 8.00E+05 | 3.34 nA | — |
| Ga-based | Graphene/GaN | 1.60E+06 | 0.6 nA | 2.1 ms; 4.2 ms |
| | GaN based p-i-n | 5.00E+06 | 1 pA | 43 ps |
| | AlGaN-based p-i-n | 1.00E+04 | 1 pA | — |

TABLE 4

| | | | Detectivity | Voltage | |
|---|---|---|---|---|---|
| | Materials | Response time | (×10¹⁰ cm Hz^{1/2}W⁻¹) | applied | Area |
| | p-Si/Tio₂ | 7 us | 6.15 × 10⁵ | 0 V | 0.64 cm² |
| Perovskite | Halide perovskite | 80 ms | 1,220 | 1 V | 1.5 × 1.5 cm² |
| | Two-dimensional | — | 1.2 × 10⁵ | 50 mV | 4 mm² |
| | hybrid perovskites | | | | |
| | C₆H₅C₂H₄NH₃)₂PbI₄ | 64 us; 52 us | 1.62 × 10⁵ | 6 V | 2500 mm² |
| | | | | | Width 20 mm; |
| | MAPbI₃ | 14 us | 7,230 | 5 V | length 2.5 um |
| | CH₃NH₃PbI₃ | 240 us | 524 | 5 V | 37.8 mm² |
| | Single-crystalline | 27.6/24.5 us | 7 × 10⁵ | 5 V | 25 um² |
| | perovskite | | | | |
| | All-Inorganic | 0.14 ms/ 0.12 ms | 480 | 0 V | 0.12 cm² |
| | Perovskite | | | | |
| | CH₃NH₃PbI₃ | 7.7 ms | 290 | 1 V | 0.08 mm² |
| Organic | PDDTT/PC₆₀BM | — | 3.9 | 0.5 V | — |
| | PCDTBT/PC₇₁BM | — | 2,010 | −5 V | 4.5 cm² |
| | PCDTBT/PC₇₀BM | 7.7/10.9 us | 3,210 | 2 V | 2.5 mm² |
| | PVK:PC₇₁BM | 200 ms | 107 | −1.5 V | 2 mm² |
| | SQ/PC₆₁BM | 1 us | 340 | 1 V | 4 mm² |
| | PCPDTBT/PC₇₀BM | — | 1,000 | 0 V | 4.5 mm² |
| 2-D | Graphene-Silicon | 0.32/0.75 ms | 4,080 | 0 V | 0.1 cm² |
| materials | MoS₂/Si | 3 us | 103 | 0 V | 3 mm × 3 mm |
| | Heterojunction | | | | |
| | PbI₂-based | 13.5 ms | 1.04 | 5 V | 9.89 pm² |
| | | | | | Width 2 mm; |
| | WS₂ Film | — | 12.2 | 5 V | length 0.1 mm |
| | | | | | 100 μm × 100 |
| | Multilayer MoS₂ | — | 1-10 | 5 | μm |
| Silicon | Si/SiGe detectors | — | 88 | 5 | 22 mm × 22 mm |
| | | | | | Diameter: 2.5 |
| | Silicon | 550/300 us | 104 | 5 V | mm |
| Other | b-AsP | 0.54/0.52 ms | 0.49 | 0 V | 9 mm² |
| | Bi₂Se₃/Si | 2.4/5.5 us | 439 | 1 | 0.03 cm² |
| | GaN | 20/60s | 5.3 × 10⁴ | 1 V | 260 × 200 mm² |
| | AlGaN | — | 260 | 25 V | 150 × 150 mm² |
| Quantum | InAs quantum dot | — | 30 | 1.4 V | Diameter: 250 |
| dot | | | | | mm |

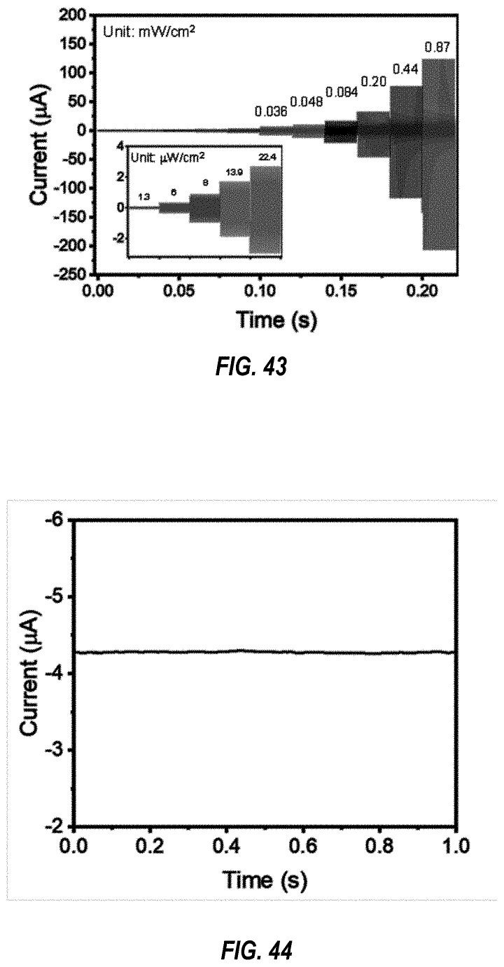

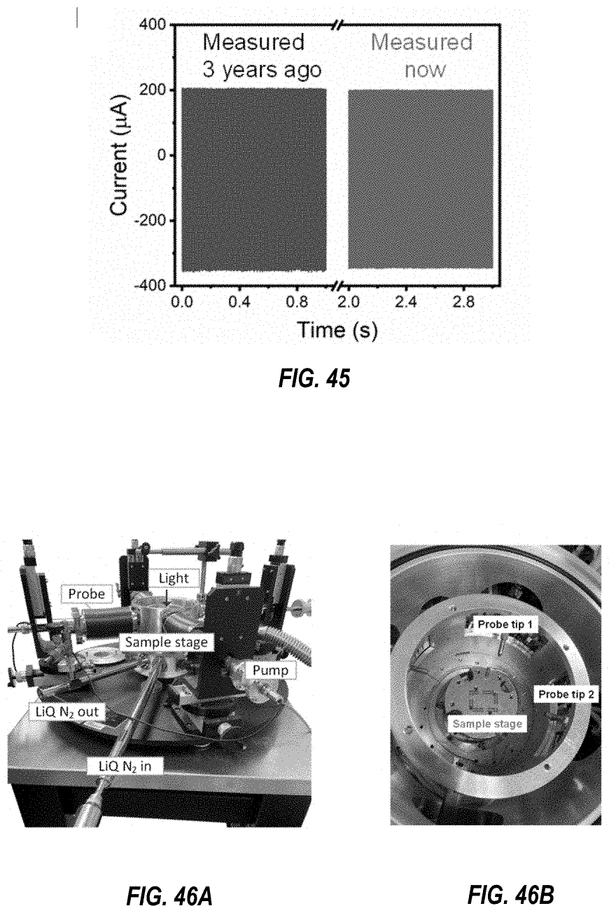

In FIG. 43, the I-t characteristic curve shows the photocurrents under various intensities ranging from 1.3 μW cm⁻² to 0.87 mW cm⁻². From the inset figure, even under the ultra-low intensity of only 1.3 μW cm⁻², the AC attains 53 nA, significantly higher than the dark current (0.18 pA), and its sensitivity achieved 3.14×10⁷%. In comparison, photodetector by the conventional PV effect has a very week photon response with a sensitivity of only 472% since the dark current is strong (4.26 μA, FIG. 44) when a bias voltage of −1 V is applied. In addition, it has exceeding durability that the output has no observable difference after being kept in the dark at the ambient conditions for 3 years (FIG. 45). Responsivity is another important parameter for a photodetector to determine the available output signal of a detector for a given input optical signal. The responsivity is the ratio of the photocurrent output signal to the power of the input optical signal, R=(I_{light}−I_{dark})/Pᵢₗₗ. The maximum responsivity R can reach 0.48 A/W, which is comparable to commercial silicon photodetectors, and it is worthy to note the AC photo-response still has a high responsivity without any external bias to promote the photodetection.

Another useful intrinsic parameter of a photodetector is the specific detectivity (D*), the ability to detect weak signals, which is given as:

$${D}^{*} = \frac{R \sqrt{A}}{\sqrt{2 e \overline{{i}_{d}}}} ,$$

when the detector is shot-noise limited by its dark current, where R the responsivity in A W⁻¹, A is the effective area of the detector in cm², e is the electron charge, and i̅_̅{̅d̅}̅ is dark current. The device exhibited a detectivity D* of 6.15×10¹⁵ Jones (1 Jones=1 cm Hz^{1/2} W⁻¹) at 0.866 mW cm⁻², which is among the best comparing with other reported results, while the detectivity of silicon photodetectors is ˜4×10¹² Jones. It is worthy to note that comparing with nanodevices, large-scale photodetectors always have a significant lower responsivity and detectivity. Our device has a large scale (0.64 cm²), and it still exhibits an extraordinary detectivity.

The external quantum efficiency ηₑ can be defined as the ratio of the number of photogenerated charge carriers contributed to the photocurrent to the number of incident photons, which can then be express as:

$${η}_{e} = \frac{h v {i}_{ph}}{e {P}_{s}} ,$$

where h is the Planck constant, v is the optical frequency, e is the elementary charge, Pₛ is the optical input power. The maximum external quantum efficiency of the detector reaches ˜86%. Above all, the photodetector based on the AC photoresponse has ultra-high sensitivity, quantum efficiency, and detectivity; at the same time, it has extremely low dark current and NEP, and fast response time.

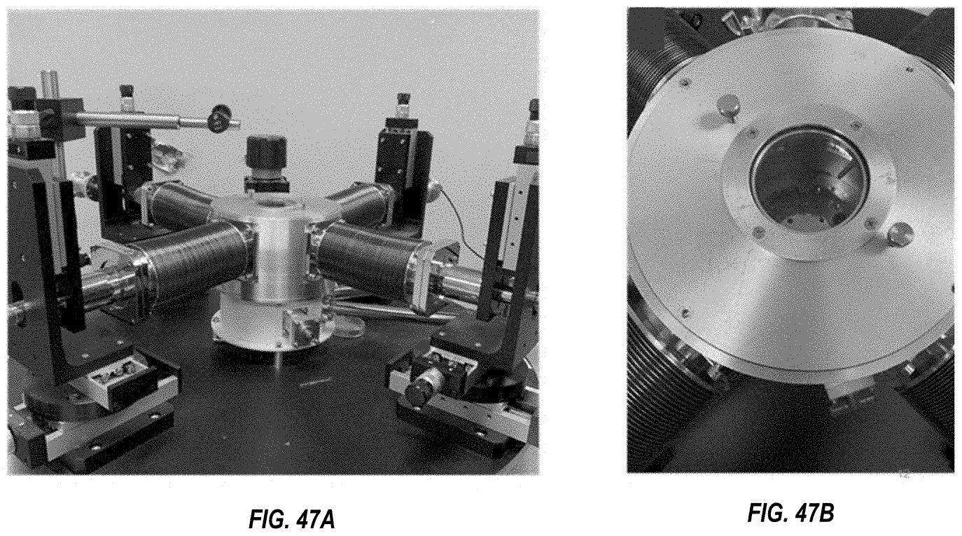

The temperature dependence of photocurrent provides valuable insights into the physics behind carrier transport. To have deep perceptions of the mechanism of the AC induced by the photons, the temperature effect on the photophysics processes is studied. Two devices of p-Si/ZnO and p-Si/TiO₂ were placed in a micro-manipulation cryogenic probe system (Janis, model ST-400-2) separately, as shown in FIGS. 46A and 46B. A pump is set to provide a vacuum environment, and the liquid nitrogen is fed to cool the chamber. The heater is installed in the chamber to adjust the temperature up to 350 K from the 78.3 K. Probe tips are connected to the sample's electrodes and the electrical meter. The chamber lid has a glass window to allow the light to go into chamber (FIGS. 47A and 47). A weak light intensity (˜0.7 μW cm⁻²) was applied to have a better view to compare the DC and AC.

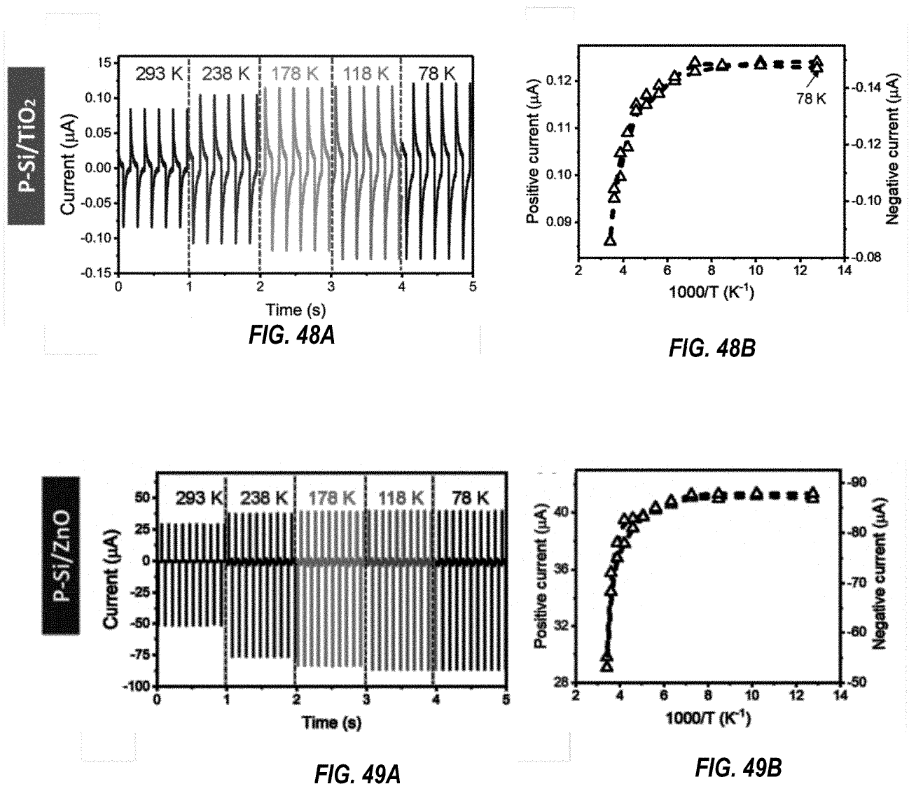

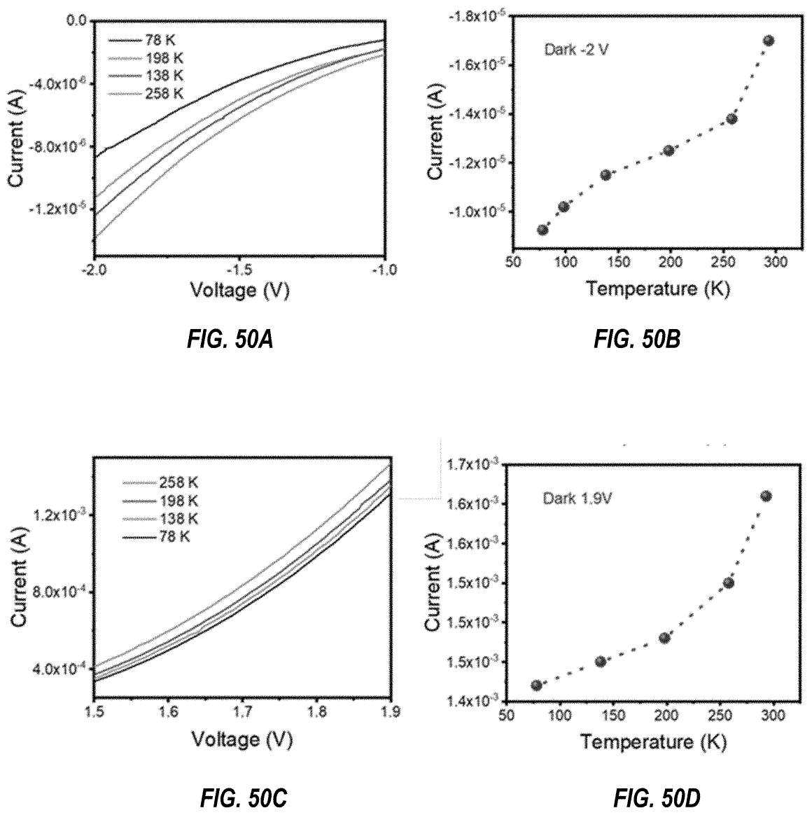

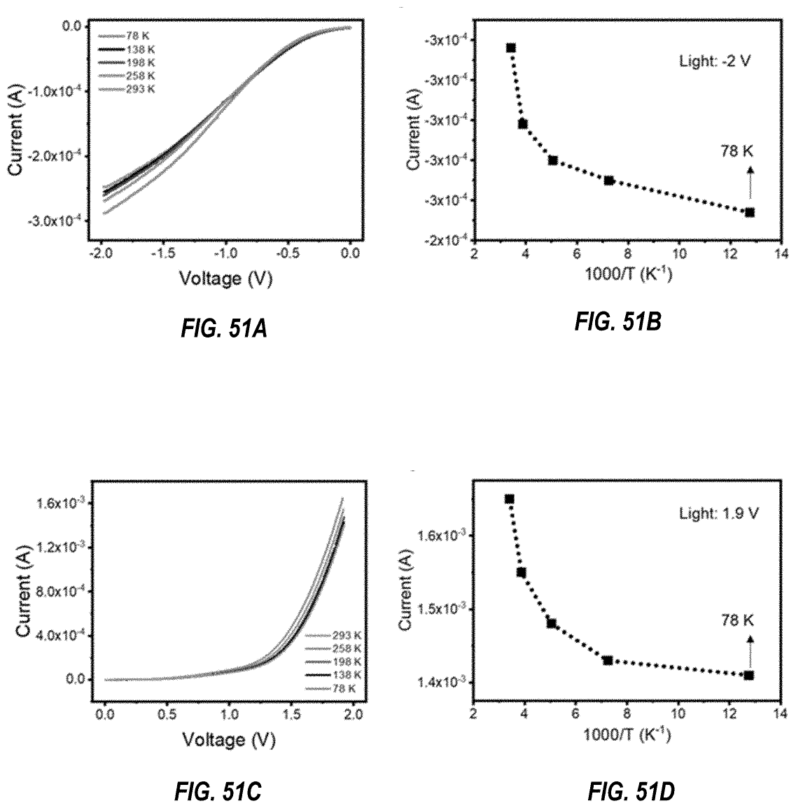

As shown in FIGS. 48A and 48B, the negative current firstly soars 62.5% with an increase from 0.08 μA to 0.13 μA as the temperature goes down from 293 K, and goes nearly flat as the temperature further decreases below 178 K. The positive current also increases from 86 nA to 120 nA firstly as the temperature goes down to 178 K, then saturates as the temperature decreases further to 78 K. The result is similar for the device of p-Si/ZnO nanowire arrays (FIGS. 49A and 49B), with a current up about 45% firstly and then goes flat as the temperature went down to 78 K from 178 K. The results show that the temperature has a strong effect on the AC output. Firstly, light is an electromagnetic wave, its power intensity does not change with temperature. From FIGS. 50A-50D, when the temperature becomes lower, the resistance increases as the dark current reduces continuously, which should not contribute to the increase of AC photocurrent here. Besides, the bandgap of silicon has an increase of 0.055 eV (Eg(T)=1.206-0.000273 T) with the decrease in temperature, so the short circuit current is inversely related to E_{g}. From the I-V curve, as shown in FIGS. 51A-51D, the DC photocurrent under the stable light has a continuous reduction of ˜13.6% as the temperature reduces from 293 K to 78 K, whereas the peaks of AC photocurrent show a different growth in this temperature range, demonstrating that the AC part has a different mechanism and physical processes from the DC photocurrent caused by the conventional photovoltaic effect.

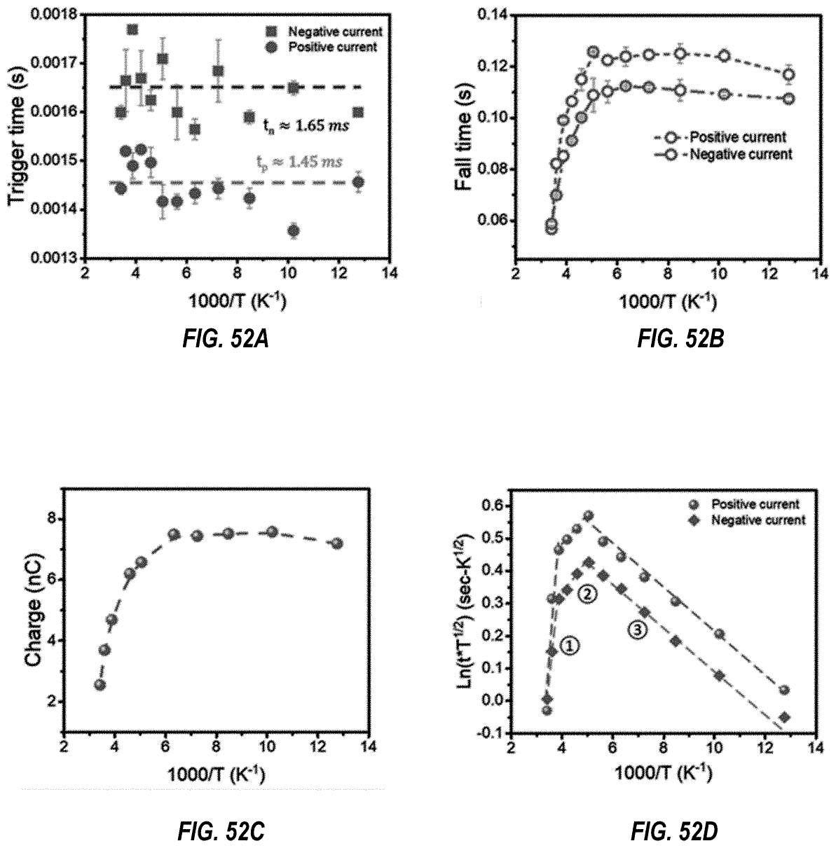

The dependence of the AC photocurrent transient on temperature provides the most direct insight into trap state levels. To investigate possible trap states that may be associated with the AC photoresponse, it is essential to study the transient response dependence on temperature, more specifically, the fall time of AC an, (t_{fall}), dependence on temperature. The fall time, typically defined as the transition time for the current to drop from the peak from 90% to 10%, is a characteristic of transition time between equilibrium states and the trapping process of excessive carriers. For better analysis and comparison, the light intensity was set to be low with a small amplitude of voltage input, so that a longer fall time is obtained due to a longer switch transition time. As shown in FIGS. 52A-52D, there is a uniform generation rate existing in the crystal and the temperature has little effect on the trigger time (defined as the transition time for the current to rise from 10% to 90% of peak). In this way, we can investigate the temperature dependence of fall time under the same initial triggering conditions. The fall times of AC photocurrents (both positive and negative currents) are nearly doubled as the temperature decreases from 293 K and shows a saturation at temperature below 178K (FIG. 52B).

Based on the experiment results, it is expected that the AC photocurrents are determined by lifetime and mobility with temperature. If we consider a simple case, when the photo excitation is retreated immediately, the generation rate of excess carriers, which previously equals the recombination rate at equilibrium states, suddenly drops and the recombination rate decreases continuously until the generation rate and recombination rate are equaled to build up a new equilibrium. In the transition time, the excess electrons and holes recombine at a rate determined by the excess minority carrier electron lifetime in the p-type semiconductor. The time behavior of excess carrier δn(t) existed in crystal can be given as following:

### Example 22: Lifetime Dependence of Excess Carriers

In a simple model, consider an infinitely large, homogeneous p-type semiconductor with a zero applied voltage, and at the condition of a uniform generation rate and a homogeneous semiconductor, We assume the low-injection condition applies.

For an extrinsic p-type semiconductor under low injection, the ambipolar transport equation becomes:

$${D}_{n} \frac{{\partial }^{2} ( δ n )}{δ {x}^{2}} + {μ}_{n} E \frac{\partial ( δ n )}{δ x} + {g}^{′} - \frac{\partial n}{{τ}_{n 0}} = \frac{\partial ( δ n )}{\partial t}$$

The parameter δn is the excess minority carrier electron concentration, τₙ₀ is the minority carrier lifetime under low injection, and Dₙ is the minority carrier electron diffusion coefficient, g′ is the generation rate of excess carriers. τₙ₀ is the minority carrier electron lifetime.

$$\frac{{\partial }^{2} ( δ n )}{δ {x}^{2}} = \frac{\partial ( δ n )}{δ x} = 0$$

First: the time behavior of excess carriers returns to thermal equilibrium.

Assume that at time t=0, a uniform concentration of excess carriers exists in the crystal, g′=0. Equation reduces to:

$$- \frac{\partial n}{{τ}_{n 0}} = \frac{\partial ( δ n )}{δ t}$$

The solution to the Equation is:

δn(t)=δn(0)e^{-l/τ}^{ₙ₀}

where δp(0) is the uniform concentration of excess carriers that exists at time t=0. The concentration of excess electron decays exponentially with time. The excess electrons and holes recombine at the rate determined by the excess minority carrier electron lifetime in the p-type semiconductor.

Second, the time dependence of excess carriers in reaching a steady-state condition. If for t<0, the semiconductor is in thermal equilibrium and for t≥0, a uniform generation rate exists in the crystal. Assuming a condition of low injection, the excess carrier concentration as a function of time can be derived. Then, the equation reduces to

$${g}^{′} - \frac{\partial n}{{τ}_{n 0}} = \frac{d ( δ n )}{dt}$$

From the equation, by setting

$$\frac{d ( δ n )}{dt} = 0 ,$$

the remaining terms simply state that the generation rate is equal to the recombination rate. The solution to this differential equation is:

δp(t)=ġτₙ₀(1−e^{-l/τ}^{ₙ₀})

A simple numerical calculation to demonstrate that how the carrier lifetime influences the excess electron concentration.

Consider p-type Si doped at N₀=10¹⁶ cm⁻³. Assume 10¹⁴ electron-hole pairs per cm³ have been created at t=0. Assume the minority carrier electron lifetime is τₙ₀.

δn(t)₁=10¹⁴e^{-l/τ}^{ₙ₀}

If the excess hole and excess electron concentration will decay to 1/e of their initial value in time t, and the time change to 2t as the temperature decreases, thus the τₙ₀ required to be double, as following:

δn(t)₂=10¹⁴e^{-2l/(2τ}^{ₙ₀}⁾

where τₙ₀ is the minority carrier lifetime, for t<0, the semiconductor is in thermal equilibrium and t≥0, the photon excitation is retreated. Carrier lifetime has a dependence on temperature characterized by a thermal emission rate given by:

$${τ}^{- 1} = {σ}_{n} {N}_{c} {ν}_{t h} exp ( - \frac{Δ E}{k T} ) ,$$

where σₙ is the capture cross-section of the trap, N_{c} is the density of states in conduction band, vₜₕ is the thermal velocity of the carriers, and ΔE is the energy depth of the trap measured relative to the conduction band edge. The increased carrier lifetime with the decreased temperature results in a larger excess carriers Δn (Supplementary Note 6) and restriction of recombination rate (the recombination rate of excess carriers is inversely proportional to the minority carrier lifetime,

$$R = \frac{δ n}{{τ}_{0}} ) .$$

Therefore, it has a larger transition time to reach a new equilibrium from previous states, as shown in FIG. 52B. And therefore, the excess electrons and holes recombine at the rate determined by the excess minority carrier lifetime in the semiconductor.

A significant increase of excess carrier would shift the quasi-Fermi levels so that electrons flow to level the imbalance of the charge redistributions at the transition time. From FIG. 52C, the transferred charge of the AC part, obtained by integration of the current I(t) over the transition time interval, gained ˜294% higher as the temperature cooled down compared with the value at 293 K, and remained unchanged over the temperature range from about 178 to 78 K. When the transition time increased 2.16 times, apparently, AC would increase 1.38 times according to the current definition, which is close to the measured result.

### Example 23: The Temperature Dependence of Mobility

The most important parameters dependent on temperature are the carrier mobility and diffusion coefficients. There are two collision or scattering mechanisms that dominate in a semiconductor and affect the carrier mobility: photon or lattice scattering, and ionized impurity scattering.

In lattice scattering, the moving carriers are scattered by a vibration of the lattice. The lattice scattering is related to the thermal motion of atoms. It is expected that the thermal agitation of the lattice becomes greater as the temperature increases, so the frequency of such scattering events increases. And the rate at which the scattering occurs is a function of temperature, as follows:

μ_{L}∝T^{-3/2}

where μ_{L} is the mobility due to the lattice scattering.

If only lattice scattering existed, the scattering theory states that the lattice vibrations decrease as the temperature decreases, the probability of a scattering event also decreases, thus the mobility increases.

The second interaction mechanism affecting carrier mobility is called ionized impurity scattering. The atoms of the lattice at low temperature are less agitated, lattice scattering is less important and the thermal motion of the carriers is also slower. Slowly moving carriers are more likely to be scattered strongly by interaction with charged ions. These impurities are ionized at room temperature so that a Coulomb interaction exists between the electrons or holes and the ionized impurities. Impurity scattering events cause a decrease in mobility with decreasing temperature. If only ionized impurity scattering existed, then:

$${μ}_{I} ∝ \frac{{T}^{3 / 2}}{{N}_{I}}$$

where μ_{I} is the mobility due to the ionized impurity scattering, N_{I} is the total ionized impurity concentration in the semiconductor. If temperature decreases, the random thermal velocity of a carrier decreases, increasing the time the carrier spends in the vicinity of the ionized impurity center, the larger the scattering effect and the smaller value of μ_{I}.

The total mobility is given by Matthiessen's rule, which is:

$$\frac{1}{{μ}_{e}} = \frac{1}{{μ}_{I}} + \frac{1}{{μ}_{L}}$$

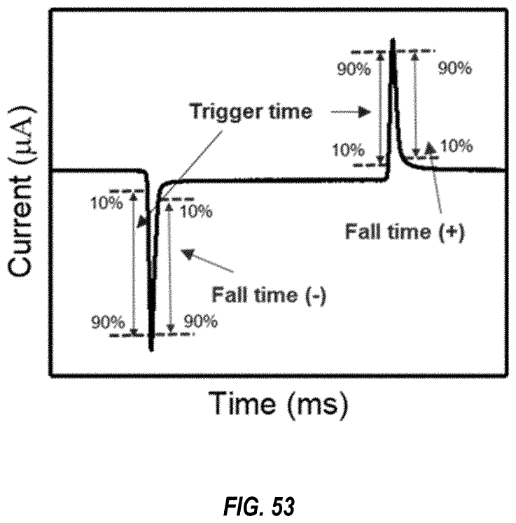

As a result, the scattering process with the lowest mobility dominates. At low temperatures, impurity scattering dominates, while at high temperatures lattice scattering dominates. Experimental measurements of electron and hole mobilities in Si, as a function of temperature, are shown in FIG. 53 and confirm this behavior.

The mobilities are strong functions of temperature due to the scattering processes, the diffusion coefficients are also strong functions of temperature. If we assume quasi-neutrality, then we have Einstein relation:

$$\frac{{D}_{n}}{{μ}_{n}} = \frac{{D}_{p}}{{μ}_{p}} = \frac{k T}{e}$$

The main temperature effects on mobility and diffusion coefficient are a result of lattice scattering and ionized impurity scattering processes.

The above results show that the AC photocurrent as a function of temperature follows the mobility dependent on temperature. According to the Matthiessen's rule, at a high-temperature range (extrinsic region), the scattering theory states that the mobility increases with decreasing temperature in the lattice-scattering range, varying approximately as T^{-3/2}, due to the decrease of the lattice vibrations decrease as the temperature decreases. While at very low temperature (ionization region), the mobility decreases with decreasing temperature because of the increased impurity scattering events caused by crystal defects, such as ionized impurities. The two scattering processes compete with each other over the temperature range. The mobility of the silicon used with a carrier concentration of 10¹⁵, increases to a maximum value as the temperature down to around 180-200 K, then nearly flat as the temperature down to 78 K, which is similar to the growth of fall time and AC photocurrent with temperature. The diffusion coefficient for electrons also changes as the temperature decreases, which can be determined from the relation between the mobility and diffusion coefficient by the Einstein Equation.

FIG. 52D illustrates the natural logarithm of the product τT^{1/2} over various temperature (1/T), plotted to account for the temperature dependence of thermal velocity. This method reveals the trap states are associated with the AC photocurrent and the energy depth of the sensitizing centers relative to the band edge. The linear region at high temperature (from 258 K to 298 K) has a mobility activation energy of ˜0.236 eV. In the intermediate range from 198 K to 258 K, the temperature dependence is much smaller than that at high temperatures suggesting that a second, smaller activation energy of 0.01 eV dominates the transport in this temperature region. At lower temperatures (in the ionization region), a third linear region with 1/T is also observed and the AC photocurrent typically plateaus below 178 K, which confirms the contribution of mobility temperature dependence to the AC photocurrent is negligible as τ is independent of temperature within the temperature range from 178 K to 78 K. The polylines in the temperature range may suggest a distribution in sensitizing center energies to be of discrete levels. Trap-induced recombination depends on mobility, which can be understood and modeled within the framework of Shockley-Read-Hall formalism. Charge recombination occurs through (midgap) trap states with discrete energy levels.

Overall, the results reveal that the AC behaves at various temperatures according to the minority carrier parameters, which include Dₙ, μₙ, and τₙ₀, that are strongly associated with the nonequilibrium excess carriers and trap states in semiconductors. More evidence reveals that the origin of the alternating currents at the transitions is caused by immediate generation or quenching of the photon-excited excessive carriers at the time when light switches, which breaks the previous equilibrium states and leads to the imbalance of the quasi-Fermi levels. A relative shift of quasi-Fermi levels may cause charges to be transferred and/or redistributed. The trap states in materials can store electrons and then are negatively charged when the switched light induces excess carriers, and/or lose electrons and positively charged when light switches back to return to the initial state, which results in a potential difference between electrodes to drive the current flow through the external circuit to balance the charges. Therefore, the light modulated by a power source or high-speed optical shutter produces a time-varying electric field between electrodes to drive electrons to flow back and forth.

It is to be understood that the embodiments and claims disclosed herein are not limited in their application to the details of construction and arrangement of the components set forth in the description and illustrated in the drawings. Rather, the description and the drawings provide examples of the embodiments envisioned. The embodiments and claims disclosed herein are further capable of other embodiments and of being practiced and carried out in various ways. Also, it is to be understood that the phraseology and terminology employed herein are for the purposes of description and should not be regarded as limiting the claims.

Accordingly, those skilled in the art will appreciate that the conception upon which the application and claims are based may be readily utilized as a basis for the design of other structures, methods, and systems for carrying out the several purposes of the embodiments and claims presented in this application. It is important, therefore, that the claims be regarded as including such equivalent constructions.

Furthermore, the purpose of the foregoing Abstract is to enable the United States Patent and Trademark Office and the public generally, and especially including the practitioners in the art who are not familiar with patent and legal terms or phraseology, to determine quickly from a cursory inspection the nature and essence of the technical disclosure of the application. The Abstract is neither intended to define the claims of the application, nor is it intended to be limiting to the scope of the claims in any way.

What is claimed is:

1. An AC generator comprising:
a substrate comprising a first material abutting a second material and forming an interface,
wherein the first material comprises a first electrode and the second material comprises a second electrode in electrical communication with the first electrode, and
wherein the substrate is configured to generate alternating current (AC) when the interface is exposed to periodic light stimulation.

2. The AC generator of claim 1, wherein the substrate is configured to generate the AC when the interface is exposed to periodic light stimulation while a bias voltage is applied to the first and the second materials, the bias voltage ranging from 0 V to about 0.2 V.

3. The AC generator of claim 1, wherein the periodic light stimulation comprises a range from about 100 nm to about 2500 nm.

4. The AC generator of claim 1, wherein the interface is exposed to the periodic light stimulation comprising modulated waveforms of a light source.

5. The AC generator of claim 4, wherein the waveforms comprises a square waveform, a sinusoidal waveform, a triangular waveform, a sawtooth waveform, a step waveform, or a pulsed waveform.

6. The AC generator of claim 1, wherein the interface is exposed to the periodic light stimulation comprising consecutively blocked and unblocked light stimulation to the interface.

7. The AC generator of claim 6, wherein the interface is exposed to the periodic light stimulation comprising consecutively blocked and unblocked light stimulation at a frequency of about 0.1 Hz to about 1 GHz.

8. The AC generator of claim 1, wherein the first material comprises a p-type material, an n-type material, an i-type material, a metal, or a semiconductor, and wherein the second material comprises a p-type material, an n-type material, an intrinsic-type material, an insulator material, a metal, or a semiconductor.

9. The AC generator of claim 1, wherein the interface comprises at least one of a p-n junction, a p-intrinsic-n junction, a p-insulator-n junction, or a metal-semiconductor junction.

10. A method for generating alternating current, the method comprising:
exposing an interface formed on a substrate to periodic light stimulation, the substrate comprising a first material abutting a second material, the interface positioned between the first material and the second material, the first material having a first electrode, and the second material having a second electrode in electrical communication with the first electrode;
generating an alternating current (AC); and
outputting the AC at the first and second electrodes.

11. The method of claim 10, wherein the method further comprises applying a bias voltage to the first and second materials, the bias voltage ranging from 0 V to about 0.2 V.

12. The method of claim 10, wherein the interface comprises at least one of a p-n junction, a p-intrinsic-n junction, a p-insulator-n junction, or a metal-semiconductor junction.

13. The method of claim 10, wherein the periodic light stimulation comprises a range from about 100 nm to about 2500 nm.

14. The method of claim 11, wherein exposing the interface to the periodic light stimulation comprises modulating waveforms of a light source.

15. The method of claim 14, wherein the waveforms comprise a square waveform, a sinusoidal waveform, a triangular waveform, a sawtooth waveform, a step waveform, or a pulsed waveform.

16. The method of claim 10, wherein exposing the interface to the periodic light stimulation comprises consecutively blocking and unblocking light stimulation to the interface at a frequency of about 0.1 Hz to about 1 GHz.

17. A sensor comprising:
a semiconductor having an interface formed between a first material and an abutting second material,
wherein the interface is configured to generate an electrical signal when exposed to periodic light stimulation.

18. The sensor of claim 17, wherein the interface is configured to generate an electrical signal when exposed to periodic light stimulation and a bias voltage is applied to the first and second materials, the bias voltage ranging from 0 V to about 0.2 V.

19. The sensor of claim 17, wherein the periodic light stimulation comprises a range from about 100 nm to about 2500 nm.

20. The sensor of claim 17, wherein the interface comprises at least one of a p-n junction, a p-intrinsic-n junction, a p-insulator-n junction, or a metal-semiconductor junction.
